(19) United States
(12) Patent Application Publication
(10) Pub. No.: US 2022/0036164 A1
(43) Pub. Date: Feb. 3, 2022

(54) NEUROMORPHIC MEMORY AND INFERENCE ENGINE STACKED WITH IMAGE SENSOR TO REDUCE DATA TRAFFIC TO HOST

(71) Applicant: Micron Technology, Inc., Boise, ID (US)

(72) Inventors: Poorna Kale, Folsom, CA (US); Amit Gattani, Granite Bay, CA (US)

(21) Appl. No.: 16/942,507

(22) Filed: Jul. 29, 2020

(51) Int. Cl. G06N 3/063; G06N 5/04; G06N 3/04; G05D 1/00; G11C 13/00

(52) U.S. Cl. CPC G06N 3/063; G06N 5/04; G06N 3/0454; G05D 2201/0213; G11C 13/004; G11C 2013/0054; G05D 1/0088

(57) ABSTRACT

Systems, methods and apparatus of integrated image sensing devices. In one example, a system includes an image sensor that generates image data. A memory device is stacked with the image sensor and stores the generated image data. A host interface communicates with a host system. The memory device includes an inference engine to generate inference results using the stored image data as input to an artificial neural network. The inference engine includes a neural network accelerator configured to perform matrix arithmetic computations on the data stored in the memory device. The host interface sends the inference results to the host system for processing.

### FIELD OF THE TECHNOLOGY

At least some embodiments disclosed herein relate to image sensing devices in general and more particularly, but not limited to, image sensors stacked with a memory device that uses an inference engine to reduce data transmission to a host system.

### BACKGROUND

Recent developments in the technological area of autonomous driving allow a computing system to operate, at least under some conditions, control elements of a motor vehicle without the assistance from a human operator of the vehicle.

For example, sensors (e.g., cameras and radars) can be installed on a motor vehicle to detect the conditions of the surroundings of the vehicle traveling on a roadway. A computing system installed on the vehicle analyzes the sensor inputs to identify the conditions and generate control signals or commands for the autonomous adjustments of the direction and/or speed of the vehicle, with or without any input from a human operator of the vehicle.

In some arrangements, when a computing system recognizes a situation where the computing system may not be able to continue operating the vehicle in a safe manner, the computing system alerts the human operator of the vehicle and requests the human operator to take over the control of the vehicle and drive manually, instead of allowing the computing system to drive the vehicle autonomously.

Autonomous driving and/or Advanced Driver Assistance System (ADAS) can use an Artificial Neural Network (ANN) for the identification of events and/or objects that are captured in sensor inputs. Examples of sensor inputs include images from digital cameras, lidars, radars, ultrasound sonars, etc.

In general, an Artificial Neural Network (ANN) uses a network of neurons to process inputs to the network and to generate outputs from the network.

For example, each neuron in the network receives a set of inputs. Some of the inputs to a neuron may be the outputs of certain neurons in the network; and some of the inputs to a neuron may be the inputs provided to the neural network. The input/output relations among the neurons in the network represent the neuron connectivity in the network.

For example, each neuron can have a bias, an activation function, and a set of synaptic weights for its inputs respectively. The activation function may be in the form of a step function, a linear function, a log-sigmoid function, etc. Different neurons in the network may have different activation functions.

For example, each neuron can generate a weighted sum of its inputs and its bias and then produce an output that is the function of the weighted sum, computed using the activation function of the neuron.

The relations between the input(s) and the output(s) of an ANN in general are defined by an ANN model that includes the data representing the connectivity of the neurons in the network, as well as the bias, activation function, and synaptic weights of each neuron. Using a given ANN model a computing device computes the output(s) of the network from a given set of inputs to the network.

For example, the inputs to an ANN network may be generated based on camera inputs; and the outputs from the ANN network may be the identification of an item, such as an event or an object.

A Spiking Neural Network (SNN) is a type of ANN that closely mimics natural neural networks. An SNN neuron produces a spike as output when the activation level of the neuron is sufficiently high. The activation level of an SNN neuron mimics the membrane potential of a natural neuron. The outputs/spikes of the SNN neurons can change the activation levels of other neurons that receive the outputs. The current activation level of an SNN neuron as a function of time is typically modeled using a differential equation and considered the state of the SNN neuron. Incoming spikes from other neurons can push the activation level of the neuron higher to reach a threshold for spiking. Once the neuron spikes, its activation level is reset. Before the spiking, the activation level of the SNN neuron can decay over time, as controlled by the differential equation. The element of time in the behavior of SNN neurons makes an SNN suitable for processing spatiotemporal data. The connectivity of SNN is often sparse, which is advantageous in reducing computational workload.

In general, an ANN may be trained using a supervised method where the parameters in the ANN are adjusted to minimize or reduce the error between known outputs resulted from respective inputs and computed outputs generated from applying the inputs to the ANN. Examples of supervised learning/training methods include reinforcement learning, and learning with error correction.

Alternatively, or in combination, an ANN may be trained using an unsupervised method where the exact outputs resulted from a given set of inputs is not known before the completion of the training. The ANN can be trained to classify an item into a plurality of categories, or data points into clusters.

Multiple training algorithms can be employed for a sophisticated machine learning/training paradigm.

### BRIEF DESCRIPTION OF THE DRAWINGS

The embodiments are illustrated by way of example and not limitation in the figures of the accompanying drawings in which like references indicate similar elements.

FIG. 1 shows an integrated image sensing device connected to a host system according to one embodiment.

FIG. 2 shows a system having a vehicle configured to collect and process sensor data according to some embodiments.

FIG. 3 shows an autonomous vehicle according to one embodiment.

FIGS. 4-6 illustrate training of artificial neural networks for prediction according to some embodiments.

FIG. 7 shows an integrated image sensing device with a neural network accelerator according to one embodiment.

FIG. 8 shows a memory component to accelerate neural network computations according to one embodiment.

FIG. 9 shows a memory capacity configured to support neural network computations according to one embodiment.

FIG. 10 illustrates the configuration of a memory region for an Artificial Neural Network (ANN) model according to one embodiment.

FIG. 11 illustrates the configuration of a memory region for the inputs to artificial neurons according to one embodiment.

FIG. 12 illustrates the configuration of a memory region for the outputs from artificial neurons according to one embodiment.

FIG. 13 shows communications between a host system and an integrated image sensing device according to one embodiment.

FIG. 14 shows communications within an integrated image sensing device according to one embodiment.

FIG. 15 shows a method implemented in an integrated image sensing device according to one embodiment.

FIG. 16 shows a sensing device that includes a memory device with a neural network accelerator according to one embodiment.

FIG. 17 shows a vehicle configured to collect and process sensor data from redundant sensors according to one embodiment.

FIG. 18 shows a vehicle configured to evaluate sensor data processing results from redundant sensors using a majority voter according to one embodiment.

FIG. 19 shows a sensing device having an image sensor stacked with a memory device according to one embodiment.

FIG. 20 shows a spiking neural network implemented using memristors according to one embodiment.

FIG. 21 shows usage of current spikes through a memristor array to detect spiking in a spiking neural network implemented using memristors according to one embodiment.

FIG. 22 shows a method implemented in a sensing device with a neural network accelerator according to one embodiment.

FIG. 23 shows a method implemented in a vehicle with redundant sensing devices according to one embodiment.

### DETAILED DESCRIPTION

At least some embodiments disclosed herein provide systems, methods and apparatus to process image data within an integrated image sensing device to reduce data traffic to a host system, such as an image sensing device configured in a motor vehicle, or another vehicle, with or without an Advanced Driver Assistance System (ADAS).

For example, an integrated image sensing device can include an image sensor, a memory device, and an inference engine configured to convert images generated by the image sensor into inference results for transmitting to a host system for further analysis and thus reduce or eliminate the need to transmit to the host system the pixel image data.

For example, the image sensor can be formed on an integrated circuit die. The inference engine can be implemented via logic circuits formed on another integrated circuit die; and memory cells of the memory device can be formed on one or more further integrated circuit dies. The integrated circuit dies of the inference engine and integrated circuit dies of the memory device can be stacked on the back of the integrated circuit die of the image sensor, connected using Through-Silicon Via (TSV) (or through wire bonding, or other interconnect techniques), and enclosed within an integrated circuit package. Optionally, the pins of the integrated circuit package of the integrated image sensing device can be configured to communicate with a host system using a standardized communication protocol for memory devices or storage devices, as if the integrated image sensing device were a storage device, or a memory chip. For example, the integrated image sensing device can be packaged to have a form factor and/or the interface of a Ball Grid Array (BGA) Solid State Drive (SSD).

Alternatively, the image sensor, the inference engine, and/or the integrated circuit memory can be enclosed in separate integrated circuit packages that are connected via a printed circuit board configured within a housing of the image sensing device. The image sensing device can be connected to a host system via a memory bus, or a peripheral bus, as if the image sensing device were a memory device, or a storage device.

The high data communication bandwidth configured within the image sensing devices allows the image sensor to capture images at a high number of frames per second than that would be allowed to be transmitted over a conventional connection from a peripheral device to a host system. The inference engine processes the images and/or performs analytics to generate inference results with a data size that is significantly smaller than the size of the pixel images generated by the image sensor. Thus, the data traffic upstream from the image sensing device to the host system can be reduced.

For example, an image sensing device according to one embodiment disclosed herein can be used in an ADAS of a vehicle (e.g., an autonomous driving system). The analytics capability of the image sensing device allows the vehicle to offload a portion of its image based ANN processing to the image sensing device and thus frees its processing power and communication bandwidth for other tasks. The vehicle can make driving decisions based on images at a frame number per second higher than that limited by the communication bandwidth of a connection between the image sensing device and a processor of the vehicle.

Image sensors in cameras used in automotive and other applications can generate millions of pixels per frame and several frames per second. This data traffic is typically routed to a Central Processing Unit (CPU) for processing. Such an arrangement can clog the CPU and ultimately result in a restriction on the number of frames per second that can be processed. The techniques of image sensing devices disclosed herein remove or reduce such restrictions.

When an integrated image sensing device having memory and an inference engine stacked with an image sensor is used, the image data is reduced to inference results that can be further processed by the CPU (e.g., in a further ANN). For example, an ANN for an ADAS can include a portion that is configured to process images from a camera. Such a portion can be configured in the inference engine of the integrated image sensing device to generate neuron outputs that is communicated from the integrated image sensing device. Instead of the image data, the neuron outputs can be transmitted from the integrated image sensing device to allow the remaining portion of the ANN of the ADAS to complete its inference.

For example, the portion of ANN implemented in the inference engine of the integrated image sensing device can perform machine learning based analytics, such as pixel segmentation, feature extraction, object detection, and/or object classification, such that the need to transmit to a host system the data about individual pixels can be reduced or eliminated.

Preferably, the memory device in the integrated image sensing device has wide input/output connection to offer high bandwidth with the image sensor and the inference engine optimized for machine learning tasks. Optionally, the memory device can include built in functions for accelerating certain ANN operations, such as dot-product and tensor access.

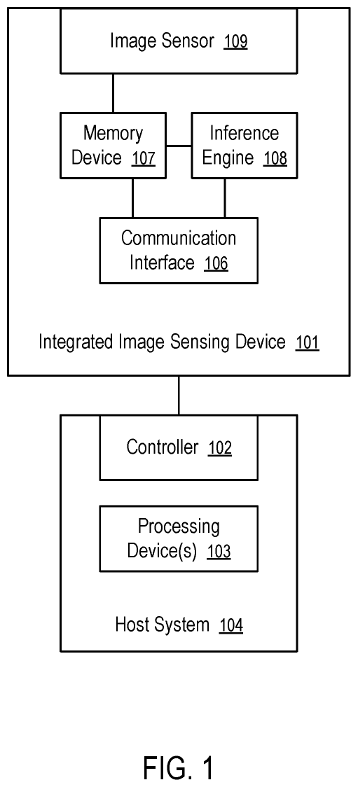

FIG. 1 shows an integrated image sensing device (101) connected to a host system (104) according to one embodiment. In FIG. 1, the integrated image sensing device (101) has an image sensor (109), a memory device (107), an inference engine (108), and a communication interface (106).

In one embodiment, the image sensor (109), the memory device (107), the inference engine (108), and the communication interface (106) are formed on multiple integrated circuit dies that are stacked to form a Three-Dimensional Integrated Circuit (3D IC). Through-Silicon Via (TSV) can be used to implement high communication bandwidth among the image sensor (109), the memory device (107), and the inference engine (108). Further, the memory device (107) can be configured to accelerate and/or optimize the operations of the inference engine (108), as discussed further below.

Optionally, the integrated image sensing device (101) can be enclosed in one integrated circuit package with input/output connections to a controller (102) of the host system (104). For example, the integrated image sensing device (101) can be package as a BGA SSD that has the image sensor (109) and the inference engine (108). For example, the connection between the integrated image sensing device (101) and the host system (104) can be in accordance with a communication protocol for a Peripheral Component Interconnect express (PCIe) bus, a Serial Advanced Technology Attachment (SATA) bus, a Universal Serial Bus (USB) bus, and/or a Storage Area Network (SAN).

In some implementations, the inference engine (108) includes programmable processing units; and the instructions for the processing units can be stored in the memory device (107) to customize the operations of the inference engine (108).

For example, an ANN model can be stored in the memory device (107); and the inference engine (108) is configured to apply the ANN model to the images from the image sensor (109) to generate inference results and store the inference results in the memory device (107). The host system (104) has one or more processing device(s) (103) and a controller (102) to access the communication interface (106) over communication link between the integrated image sensing device (101) and the host system (104). The host system (104) can issue read commands to retrieve the inference results stored in the memory device (107). For example, the communication interface (106) can include an interface in accordance with a Non-Volatile Memory Host Controller Interface Specification (NVMHCIS) or NVM Express (NVMe). For example, the NVMe interface of the integrated image sensing device (101) can be used to receive data and commands from the host system (104). For example, the host system (104) can send write commands to store the ANN model into the memory device (107) of the integrated image sensing device (101) and read commands to retrieve inference results of the inference engine (108) from the memory device (107) in accordance with an NVMe protocol. For example, the communication interface (106) can be configured to allow the host system (104) to access the memory device (107) of the integrated image sensing device (101) as a Solid State Drive (SSD). Optionally, the communication interface (106) (or another interface) can include an NVMe interface for communicating with an external Solid State Drive (SSD) (e.g., separate from the integrated image sensing device (101) and the host system (104)) to store inference results generated by the inference engine (108) and/or image data generated by the image sensor (109) or derived from the images generated by the image sensor (109).

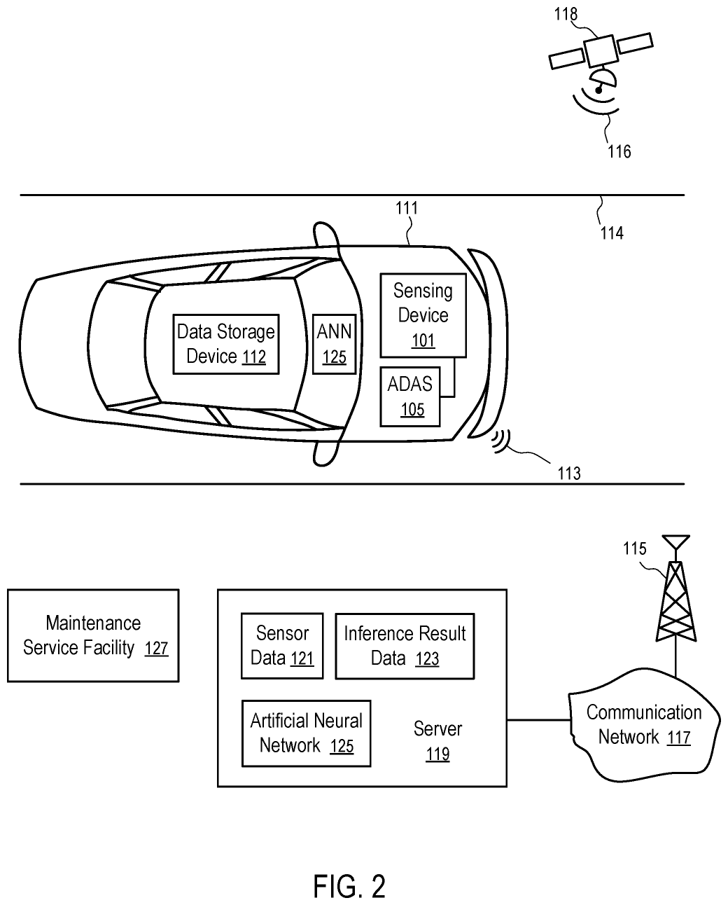

For example, the integrated image sensing device (101) can be configured in a vehicle illustrated in FIG. 2.

FIG. 2 shows a system having a vehicle (111) configured to collect and process sensor data according to some embodiments.

The vehicle (111) in FIG. 2 has a data storage device (112), an image sensing device (101) (e.g., as illustrated in FIG. 1), an ANN (125), and an ADAS (105) configured to process sensor data, including inputs from the image sensing device (101), to generate control signals for the vehicle (111).

In general, one or more sensors (e.g., 101) can be configured on the vehicle (111) to generate senor data input to the ADAS (105) and/or the data storage device (112). The data storage device (112) and/or the ADAS (105) can be configured to use the ANN (125) to generate inference results. The inference results can include a control signal for operating or driving the vehicle (111), a suggestion for a maintenance service of the vehicle (111), etc.

In some implementations, at least a portion of the data generate by the sensors (e.g., 101) is used in both the ADAS (105) for driver assistance and in the ANN (125) for maintenance prediction. Optionally, the output of the ANN (124) can be used in both the data storage device (112) and in the ADAS (105). The ANN (125) can be part of the ADAS (105).

The image sensing device (101) can be configured in a digital camera, lidar, radar, ultrasound sonar, etc. The inference engine (108) of the image sensing device (101) is configured to process the images within the sensing device (101) and communicate its inference results to the ADAS (105), the ANN (125) and/or the data storage device (112).

Optionally, the ADAS (105) can selectively requests the sensing device (101) to transmit selected images from the sensing device (101), when the inference outputs from the sensing device (101) satisfy certain requirements, or when the ADAS (105) or the ANN (125) determines a need to further analyze the images that generate the inference results from the sensing device (101). Such images can be part of sensor data (121) is that further analyzed to further train the ANN (125) on the server (119) to generate desired inference results (e.g., 123).

For example, when the object recognition or classification in the sensing device (101) and/or in the ADAS (105) encounters unknowns, difficulties, uncertainties, or when a situation is to be further analyzed, the ADAS (105) can request the sensing device (101) to transmit the corresponding images for storing in the data storage device (112). The stored data can be subsequently further processed by a server (119) and/or a maintenance service facility (127).

In general, the vehicle (111) can have other sensors that provide inputs for the ADAS (105), such as brake sensors, speed sensors, acceleration sensors, airbag sensors, a GPS (Global Positioning System) receiver, audio sensors/microphones, vibration sensors, force/stress sensors, deformation sensors, motion sensors, temperature sensors, etc. Some of the sensors (101) can be configured primarily to monitor the environment of the vehicle (111) for driving decisions and/or assistances; and other sensors (101) can be configured primarily to monitor the operating and/or health conditions of one or more component of the vehicle (111), such as an internal combustion engine, an exhaust system, an electric motor, a brake, a tire, a battery, etc.

In general, the outputs of the sensor(s) (e.g., 101) as a function of time are provided as a sensor data stream to the ADAS (105) and/or the ANN (125) to provide driver assistance (e.g., autonomous driving) and maintenance prediction. In FIG. 2, the image sensing device (101) is further configured to provide its inference results generated from its images as part of the sensor data stream, instead of transmitting the images to the main processor of the vehicle (111) implementing the ANN (125). Thus, the data size of the sensor data stream can be reduced, the communication bandwidth from the sensing device (101) to the ADAS (105) and/or the data storage device (112) can be reduced, and the computation load on the ADAS (105) and/or the data storage device (112) can be reduced.

The ANN (125) can include an SNN configured to classify time-based variations of sensor data and/or detect deviation from known patterns of sensor data of the vehicle (111). When the ANN (125) detects the deviation from known patterns, the sensor data corresponding to the deviation can be stored in the data storage device (112) for further analysis and/or for further training of the ANN (125).

The data storage device (112) of the vehicle (111) can be configured to record sensor data for a period of time that can be used in the ANN (125) for predictive maintenance and/or used to further train the ANN (125). The maintenance service facility (e.g., 127) can download the sensor data (121) from the data storage device (112) and provide the sensor data (121) and the corresponding inference result data (123) to the server (119) to facilitate the training of the ANN (125).

Optionally, or in combination, the data storage device (112) is configured with a machine learning module to customize and/or train the ANN (125) installed in the vehicle (111).

The vehicle (111) can have a wireless communication device to communicate with a remote server (119) via wireless signals (113) and a communication network (117). The remote server (119) is typically configured at a location away from a road (114) on which the vehicle (111) is in service. For example, the vehicle (111) may provide some sensor data (121) to the server (119) and receive update of the ANN (125) from the server (119).

The communication network (117) can be a cellular phone network having one or more base stations (e.g., 115) to receive the wireless signals (e.g., 113). Alternatively, or in combination, the communication network (117) can include the Internet, where the wireless local area network signals (e.g., 113) transmitted by the vehicle (113) is received in an access point (e.g., 115) for further communication to the server (119). In some implementations, the vehicle (111) uses a communication link (116) to a satellite (118) or a communication balloon to communicate with the server (119).

The server (119) can also communicate with one or more maintenance service facilities (e.g., 127) to receive the sensor data (121) and/or the desired inference result data (123) of vehicles (e.g., 111).

For example, the desired inference result data (123) can be generated by a human operator inspecting the sensor data (121) (e.g., images from the image sensing device (101)) and/or relevant conditions of the vehicle (111). For example, the desired inference result data (123) can include inspection records and/or service records of components of the vehicles (e.g., 111). For example, the inspection records and/or service records can indicate the degree of wear and tear of components inspected during their services at the maintenance service facilities (e.g., 127), the identification of failed or malfunctioning components, etc. The sensor data (121) of the vehicles (e.g., 111) obtained in a time period relevant to the desired inference result data (123) can be used to train an ANN (125) at the server (119) to improve inference capability of the ANN (125).

The updated ANN (125) can be installed in the vehicle (111) at the maintenance service facility (127). Alternatively, the update ANN (125) can be transmitted to the vehicle (111) to update the vehicle (111) over the air.

A portion of the ANN (125) responsible for the processing of images generated in the image sensing device (101) can be configured in the memory device (107) for the inference engine (108) of the image sensing device (101). The inference engine (108) processes images generated in the image sensing device (e.g., generated by the image sensor (109)) and causes the inferences results generated from the images to be transmitted from the image sensing device (101) to the ADAS (105). Thus, the data traffic from the sensing device (101) to the ADAS (105) can be reduced without sacrificing the quality of data inferred from the images.

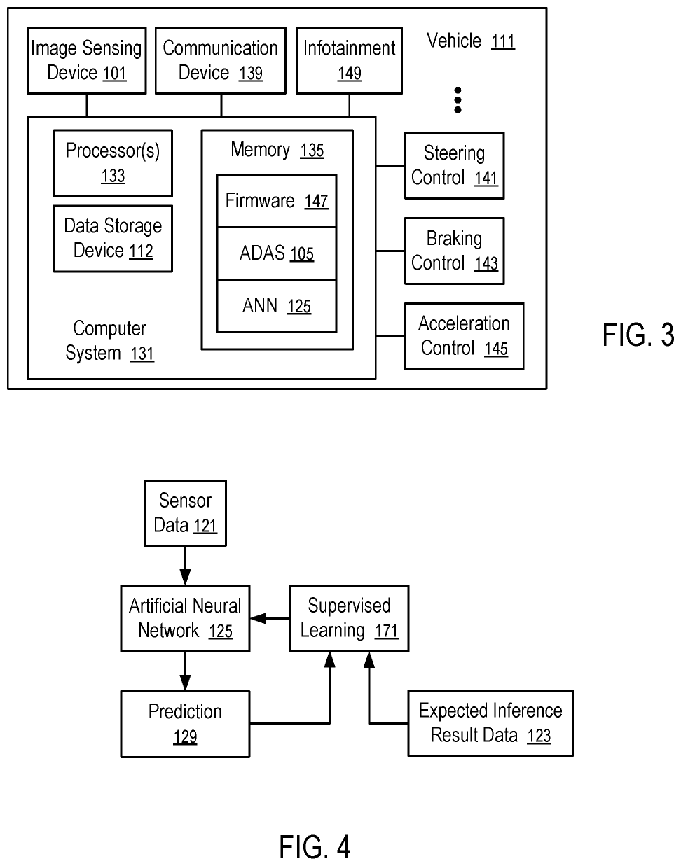

FIG. 3 shows an autonomous vehicle (111) according to one embodiment. For example, the vehicle (111) in the system of FIG. 2 can be implemented using the autonomous vehicle (111) of FIG. 3.

In general, the vehicle (111) can include an infotainment system (149), a communication device (139), one or more sensors (e.g., 101), and a computer system (131) that is connected to some controls of the vehicle (111), such as a steering control (141) for the direction of the vehicle (111), a braking control (143) for stopping of the vehicle (111), an acceleration control (145) for the speed of the vehicle (111), etc. In some embodiments, the vehicle (111) in the system of FIG. 2 has a similar configuration and/or similar components.

The vehicle (111) of FIG. 3 is configured with an Advanced Driver Assistance System (ADAS) (105). The ADAS (105) of the vehicle (111) can have an Artificial Neural Network (ANN) (125) for object detection, recognition, identification, and/or classification, based on images generated in the image sensing device (101). An image processing portion of the ANN (125) can be implemented using the integrated image sensing device (101) of FIG. 1.

At least a portion of the ANN (125) is implemented in the image sensing device (101) using its integrated inference engine (108).

For example, a portion of the ANN (125) that operates based on the images generated in the image sensing device (101) can be stored in the image sensing device (101). The inference engine (108) performs the communication according to the portion of the ANN (125) such that the amount of communications from the imaging sensing device (101) to the computer system (131) of the vehicle (111) include neuron outputs and/or inference results from the portion of the ANN (125) implemented in the image sensing device (101), but not the image data of individual pixels.

In some implementations, the computation of the portion of the ANN (125) implemented in the image sensing device (101) does not depend on sensor data that is not generated in the image sensing device (101).

Alternatively, the computation of the portion of the ANN (125) implemented in the image sensing device (101) can further be based on sensor data not generated in the image sensing device (101). For example, the computer system (131) provides the sensor data to image sensing device (101) (e.g., by writing the sensor data into the memory device (107) through the communication interface (106)). By combining the sensor data provided by the computer system (131) and the image data generated by the image sensing device (101) according to the portion of the ANN (125) that is stored/implemented in the image sensing device (101), the amount of inference results from the image sensing device (101) can be reduced (e.g., in some ways of partitioning the ANN (125)). When data traffic of sending the relevant sensor data to the image sensing device (101) is smaller than the reduction in data size in inference results, sending the relevant sensor data for processing in the image sensing device (101) can be beneficial in reducing the overall communication traffic between the image sensing device (101) and the computer system (131) of the vehicle (111). Optionally, the selection of the portion of the ANN (125) for implementation in the image sensing device (101) can be based at least in part on the minimization of the data traffic between the image sensing device (101) and the computer system (131).

The computer system (131) of the vehicle (111) can include one or more processors (133), a data storage device (112), and memory (135) storing firmware (or software) (147), including the computer instructions and data models for ADAS (105).

Sensors of the vehicle (111) can include a visible light camera, an infrared camera, a lidar, radar, or sonar system, a peripheral sensor, a Global Positioning System (GPS) receiver, a satellite positioning system receiver, a brake sensor, and/or an airbag sensor. Further, the sensors of the vehicle (111) can include audio sensors (e.g., microphone) configured to monitor noises from various components and locations in the vehicle (111), a vibration sensor, a pressure sensor, a force sensor, a stress sensor, and/or a deformation sensor configured to measure loads on a component of the vehicle (111), accelerometers and/or gyroscope sensors measuring the motions of some components of the vehicle (111), etc. Such sensors can be used to monitor the operating status and/or health of the components for predictive maintenance.

The sensor(s) (e.g., 101) can provide a stream of real time sensor data to the computer system (131). The sensor data generated by an image sensing device (101) of the vehicle (111) can include an image that captures an object using a camera that images using lights visible to human eyes, or a camera that images using infrared lights, or a sonar, radar, or LIDAR system. Preferably, the image is processed by the inference engine (108) of the image sensing device (101) to generate inference results as the output of the image sensing device (101) and thus reduce or eliminate the need to transmit pixel image data to the computer system (131).

For example, a camera having the image sensing device (101) can be used to obtain roadway information for the travel of the vehicle (111), which can be processed by the ANN (125) to generate control signals for the vehicle (111). For example, a camera having the image sensing device (101) can be used to monitor the operation state/health of a component of the vehicle (111), which can be processed by the ANN (125) to predict or schedule a maintenance service.

The infotainment system (149) of the vehicle (111) can be used to present data and/or inference results from the image sensing device (101). For example, compressed images with reduced resolution and refreshing frequency can be generated in the image sensing device (101) and transmitted to the infotainment system (149) for presentation to an occupant of the vehicle (111). Optionally, the communication device (139) can establish a connection to a mobile device of an occupant of the vehicle (111) to make the presentation.

When the vehicle (111) is configured with an ADAS (105), the outputs of the ADAS (105) can be used to control (e.g., 141, 143, 145) the acceleration of the vehicle (111), the speed of the vehicle (111), and/or the direction of the vehicle (111), during autonomous driving.

FIGS. 4-6 illustrate training of artificial neural networks (125) for prediction according to some embodiments.

In FIG. 4, a module (171) of supervised machine learning is used to train an artificial neural network (125) to minimize the differences between the prediction (129) generated from the sensor data (121) and the desired inference result data (123).

For example, the sensor data (121) can include an image showing an object; and the desired/expected inference result data (123) can identify an image region occupied by the object, a feature of the object, a classification of the object, an identity of the object, etc.

For example, the sensor data (121) can include an image surrounding of the vehicle (111); and the desired/expected inference result data (123) can include preferred control inputs for the steering control (141), the braking control (143), and the acceleration control (145).

The desired/expected inference result data (123) can be generated by a human operator. For example, the sensor data (121) can be used to construct a virtual reality demonstration of a situation encountered by the vehicle (111), including images from the image sensing device (101) showing an environment of the vehicle (111); and the desired/expected inference result data (123) can include responses generated by a human operator responsive to the virtual reality demonstration of the situation.

The supervised machine learning module (171) can adjust the artificial neural network (125) to reduce/minimize the difference between the prediction (129) generated based on the sensor data (121) and the desired/expected inference result data (123) generated by a human operator.

The supervised learning (171) of FIG. 3 can be applied in the server (119) based on the sensor data of a population of vehicles and corresponding desired/expected inference result data (123) to generate a generic ANN for the population of the vehicles.

The supervised learning (171) of FIG. 3 can be applied in the vehicle (111) based on the sensor data of the vehicle and inference result data (123) to generate a customized/personalized ANN (125). For example, a generic ANN (125) can be initially used in the vehicle (111); and the sensor data of the vehicle (111) and desired/expected inference result data (123) specific to the vehicle (111) can be used to further train the ANN (125) of the vehicle for customization/ personalization of the ANN (125) in the vehicle (111).

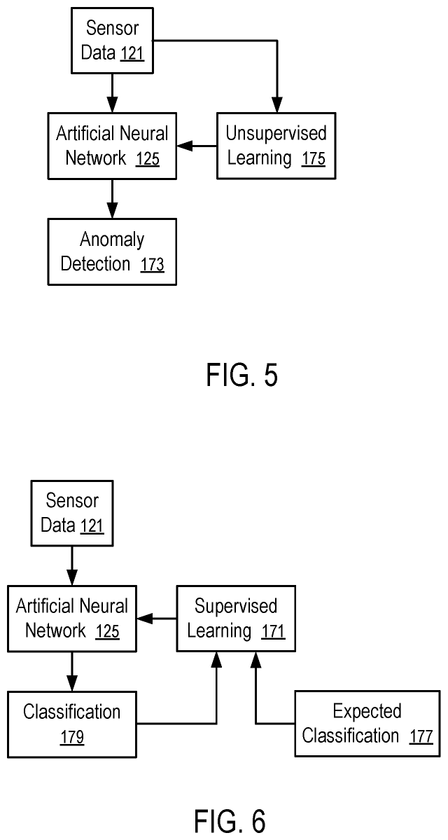

In FIG. 5, a module (175) of unsupervised machine learning is used to train or refine an artificial neural network (125) to facilitate anomaly detection (173). The unsupervised machine learning module (175) is configured to adjust the ANN (e.g., SNN) to generate the normal classification, clustering, or recognized patterns in the sensor data (121) such that a degree of deviation from the normal classification, clustering, or recognized patterns in the sensor data (121) can be used to signal the detection (173) of anomaly.

For example, anomaly detection (173) can be used to preserve the sensor data (121) associated with anomaly for further analysis. In response to anomaly detection (173) in the vehicle (111), the computer system (131) can issue read command to the image sensing device (101) to retrieve image data associated with the anomaly from the image sensing device (101) and store the retrieved image data in the data storage device (112). The image data associated with the anomaly can be temporarily preserved in the memory device (107) of the image sensing device (101) and loaded to the data storage device (112) over a period of time using available communication bandwidth between the image sensing device (101) and the data storage device (112) without impacting the normal operations of the ADAS (105).

When the vehicle (111) is in the maintenance service facility (127), the image data (and other sensor data) associated with the anomaly can be retrieved from the data storage device (112) to generate desired/expected inference result data (123) for further training of the ANN (125) using a supervised learning (171) of FIG. 4.

Optionally, a supervised machine learning (171) can be used to train the ANN (125), as illustrated in FIG. 6. The supervised learning (171) can be used to minimize the classification differences between the predictions (179) made using the ANN (125) according to the sensor data (121) and the expected classification (177).

For example, in absence of an accident, a near accident event, or a user input indicating an abnormal condition, a classification of “normal” can be assumed. An accident, a near accident event, or a user input can be used to identify an expected classification of “abnormal” for the sensor data leading to the accident, event, or user input. The supervised machine learning (171) can be used to train the artificial neural network (125) to make the classification (179) with reduced/minimized differences from the expected classification (177).

Optionally, the integrated image sensing device (101) can be configured to accelerate the computations of a portion of the artificial neural network (ANN) (125) implemented via the inference engine (108).

For example, the inference engine (108) can include a neural network accelerator (159) specialized to perform at least part of the computations involving the artificial neural network (ANN) (125), such as dot-product of vectors and tensors, multiply and accumulation operations, etc. Optionally, some ANN processing not involving the images generated by the image senor (109) can also be performed in the integrated image sensing device (101) (e.g., to reduce the computation load on the computer system (131) of the vehicle (111)).

The computations configured in the integrated image sensing device (101) can be used to reduce the amount of data to be transmitted to the processor(s) (133) to use or apply the ANN (125) and/or reduce the computation tasks of the processor(s) (133) in evaluating the outputs of the ANN (125) and/or in training the ANN (125). Such an arrangement can result in faster output from the integrated image sensing device (101) and/or lower energy usage, since the data would not have to be moved in and out of the integrated image sensing device (101) to a dedicated, standalone neural network accelerator. The computation capability of the integrated image sensing device (101)) in processing data related to the ANN (125) enables the computer system (131) of the motor vehicle (111) to have computational resources and communication bandwidth for mission critical tasks (e.g., autonomous driving by the ADAS (105)).

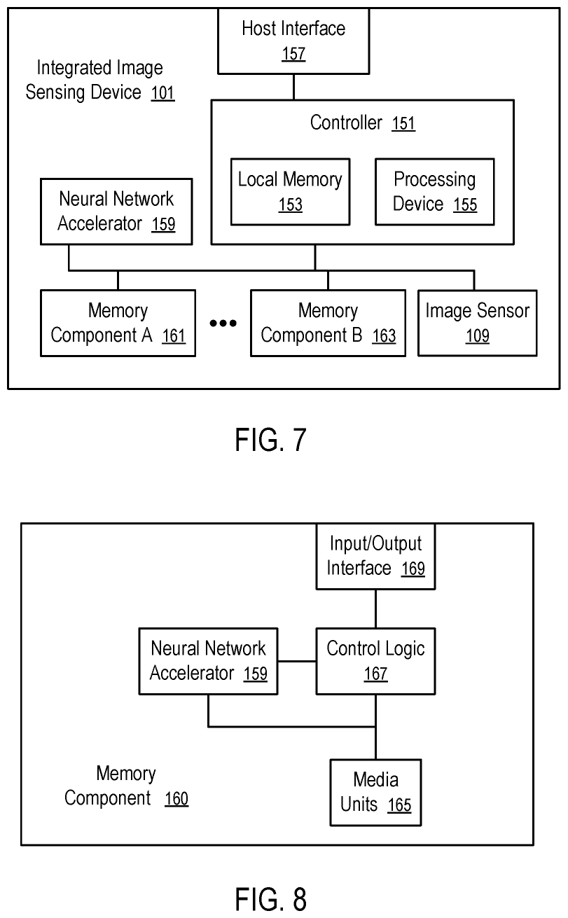

FIG. 7 shows an integrated image sensing device (101) with a neural network accelerator (159) according to one embodiment. For example, the integrated image sensing device (101) of FIG. 7 can be used to implement the image sensing device (101) of the vehicle (111) illustrated in FIG. 2 or 3.

In FIG. 7, the integrated image sensing device (101) has a host interface (157) configured to communicate with a host processor (e.g., 133 in FIG. 3) or a host system (e.g., 104 in FIG. 1). For example, the communication between the host processor (e.g., 133 or 104) and the host interface (157) can be, at least in part, in accordance with a communication protocol for a Peripheral Component Interconnect express (PCIe) bus, a Serial Advanced Technology Attachment (SATA) bus, a Universal Serial Bus (USB) bus, and/or a Storage Area Network (SAN).

For example, the host interface (157) can be configured to be similar to a host interface of a data storage device (e.g., 112).

For example, the host computer system (131 or 104) can communicate with the host interface (157) to retrieve inference results generated by the integrated image sensing device (101) from the images from the image sensor (109), instead of the images, to reduce the data traffic going through the host interface (157).

Optionally, the host interface (157) can be further used to receive, in the image sensing device (101), sensor data (121) generated by other sensors of the vehicle (111); and the sensor data (121) and the images from the image sensor (109) are combined in a portion of the ANN (125) that is implemented in the integrated image sensing device (101) to generate inference results.

In FIG. 7, each of the memory components (161 to 163) can be a memory integrated circuit configured to store data. The integrated circuit dies of the memory components (161 to 163) can be stacked to the back of the image sensor (109); and through-silicon vias between the image sensor (109) and the integrated circuit dies of the memory components (161 to 163) can be used to provide high communication bandwidth for storing the images generated by the image sensor (109) into at least some of the memory components (161 to 163) for processing by the controller (151) and/or the neural network accelerator (159). For example, different sections of the image sensor (109) can store image data to different memory components (161 to 163), or different sections of a memory component (e.g., 161 or 163), using through-silicon vias.

The neural network accelerator (159) and the controller (151) can be implemented via logic circuits formed on one or more integrated circuit dies that are further stacked on the integrated circuit dies of the memory components (161 to 163). Through-silicon vias between the integrated circuit die(s) of the neural network accelerator (159) and the controller (151) and the integrated circuit dies of the memory components (161 to 163) can be used to provide high communication bandwidth for processing the images stored in the memory components (161 to 163) to generate inference results. The inference results can be stored in the local memory (153) of the controller (151) and/or some of the memory components (161 to 163) for retrieval by the host system (104), such as the computer system (131) of the vehicle (111). For example, different memory components (161 to 163), or different sections of a memory component (e.g., 161 or 163), can use through-silicon vias to facilitate parallel access for different portions of the neural network accelerator (159), the controller (151), and the image sensor (109).

In general, some memory integrated circuits are volatile and require power to maintain the stored data; and some memory integrated circuits are non-volatile and can retain the stored data even when not powered. The memory components (161 to 163) can include volatile memory and/or non-volatile memory. The memory components (161 to 163) can implement different types of memory or a same type of memory.

Examples of non-volatile memory include flash memory, memory units formed based on negative-and (NAND) logic gates, negative-or (NOR) logic gates, Phase-Change Memory (PCM), magnetic memory (MRAM), resistive random-access memory, cross point storage and memory devices. A cross point memory device can use transistor-less memory elements, each of which has a memory cell and a selector that are stacked together as a column. Memory element columns are connected via two lays of wires running in perpendicular directions, where wires of one lay run in one direction in the layer is located above the memory element columns, and wires of the other lay is in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include Read-Only Memory (ROM), Programmable Read-Only Memory (PROM), Erasable Programmable Read-Only Memory (EPROM) and Electronically Erasable Programmable Read-Only Memory (EEPROM) memory, etc. Examples of volatile memory include Dynamic Random-Access Memory (DRAM) and Static Random-Access Memory (SRAM).

The integrated image sensing device (101) can have a controller (151) that includes volatile local memory (153) and at least one processing device (155).

The local memory of the controller (151) can be an embedded memory configured to store instructions for performing various processes, operations, logic flows, and routines that control operation of the processing device (155), including handling communications between the integrated image sensing device (101) and the processor(s) (e.g., 133) of the vehicle (111), and other functions described herein. Optionally, the local memory (151) of the controller (151) can include Read-Only Memory (ROM) for storing micro-code and/or memory registers storing, e.g., memory pointers, fetched data, etc., and/or volatile memory, such as Dynamic Random-Access Memory (DRAM) and Static Random-Access Memory (SRAM).

In FIG. 7, the integrated image sensing device (101) includes a neural network accelerator (159) coupled to the controller (151) and/or the memory components (161 to 163).

For example, the neural network accelerator (159) can be configured to perform matrix arithmetic computations more efficiently than the processing device (155) of the controller (151). The computations involving ANN (125) have matrix multiplication and accumulation operations, which can be computational intensive for a generic processor (e.g., 133, 155). Using the neural network accelerator (159) to perform the matrix arithmetic computations can reduce the data to be transmitted to the processor(s) (133) of the vehicle (111) and reduce the computation workload for the processor(s) (133, 155).

When the ANN (125) includes a Spiking Neural Network (SNN), the simulation of the differential equation(s) for controlling the activation level of SNN neurons can be computationally intensive for a generic processor (e.g., 133, 155). Optionally, the neural network accelerator (159) can use special hardware to simulate the differential equation(s) and thus improve the computational efficiency in implementing the SNN.

In some implementations, the neural network accelerator (159) is an integrated circuit device separate from the controller (151) and/or the memory components (161 to 163). Alternatively, or in combination, a neural network accelerator (159) is integrated with the controller (151) in an integrated circuit die. Alternatively, or in combination, a portion of the neural network accelerator (159) can be integrated on the integrated circuit die(s) of at least one of the memory components (161 to 163), as illustrated in FIG. 8.

FIG. 8 shows a memory component (160) to accelerate neural network computations according to one embodiment. For example, each or some of the memory components (161 to 163) in FIG. 7 can be implemented using a memory component (160) of FIG. 8.

In FIG. 8, the memory component (160) can be formed on an integrated circuit die. An input/output (I/O) interface (169) of the memory component (160) is configured to process input/output signals for the memory component (160). For example, the input/output signals can include address signals to specify locations in the media units (165) and data signals representing data to be written in the media units (165) at the locations specified via the address signals, or data retrieved from the locations in the media units (165).

In FIG. 8, a neural network accelerator (159) is coupled with the control logic (167) and/or the media units (165) to perform computations that are used in the evaluation of the output of a portion of an ANN (125) and/or in the training of the ANN (125).

For example, the input/output interface (169) can receive addresses that identify matrices that are stored in the media units and that are to be operated upon via the neural network accelerator (159). The memory component (160) can provide the computation results of the neural network accelerator (159) as the output data responsive to the addresses, store the output data in a buffer for further operations, store the output data into a location in the media units (165) specified via the address signals. Thus, the computations performed by the neural network accelerator (159) can be within the memory component (160), which is close to the media units (165) in which the matrix data is stored.

For example, the state data of SNN neurons can be stored in the media units (165) according to a predetermined pattern. The neural network accelerator (159) can automatically update the states of the SNN neurons according to the differential equation(s) for controlling the activation level of SNN neurons over time. Optionally, the neural network accelerator (159) is configured to process spiking of neurons in the neural network. Alternatively, the neural network accelerator (159) of the integrated image sensing device (101) and/or the processor(s) (133) can be configured to process the spiking of neurons and/or accumulation of inputs to the SNN.

For example, the image sensor (109) generates images at a predetermined frequency. Each image is stored into the memory components (161 to 163) in a cyclic way where the newest image writes over the oldest image. The memory components (161 to 163) further store a portion of ANN (125) of the vehicle (111) responsible for processing of the images from the image sensor (109). The controller (151) processes the images in the memory components (161 to 163) according to the portion of ANN (125) to generate inference results. The inference results are stored in the memory components (161 to 163) and/or in the local memory (153) of the controller (151) for reading by the host system (104), such as the computer system (131) of the vehicle (111).

Optionally, the integrated image sensing device (101) further receives a sensor data stream from at least one sensor configured on the vehicle (111) and generate the inference results based on the sensor data stream and the images from the image sensor (109) according to the portion of ANN (125) stored in the memory components (161 to 163).

A neural network accelerator (159) configured within the integrated image sensing device (101) performs at least a portion of computations based on an artificial neural network (125), the images from the image sensor (109), and the sensor data stream.

Optionally, the neural network accelerator (159) can be configured on an integrated circuit die that is separate from a controller (151) and/or separate from the memory components (161 to 163).

Optionally, the neural network accelerator (159) can be configured on an integrated circuit die that includes a controller (151) of the integrated image sensing device (101), or memory component (160, 161 or 163) of the integrated image sensing device (101).

The neural network accelerator (159) can be configured to perform computations, such as matrix arithmetic computations for ANN and/or or differential equation simulations for SNN, using data stored in the integrated image sensing device (101).

Examples of the matrix arithmetic computations include matrix multiplication and accumulation operations. After a computation to generate a result of the matrix arithmetic computations using a data stored in the integrated image sensing device (101), the neural network accelerator (159) can provide the result as output of the integrated image sensing device (101) in data retrieval operations (e.g., in response to a read command). Alternatively, or in combination, the result of the matrix arithmetic computation can be buffered in the integrated image sensing device (101) as operand for a next matrix computation performed in combination with a matrix of data retrieved from the non-volatile memory via a read command received in the host interface (157).

When the Artificial Neural Network (ANN) (125) includes a Spiking Neural Network (SNN), the neural network accelerator (159) can be configured to simulate a differential equation controlling activation levels of neurons in the Spiking Neural Network (SNN). Optionally, the memory component (160) is configured to store states of the neurons in the spiking neural network according to a predetermined pattern; and the neural network accelerator is configured to automatically update the states of the neurons over time according to the differential equation. For example, the neural network accelerator (159) can be configured to train the Spiking Neural Network (SNN) via unsupervised machine learning to detect anomaly.

The computations performed by the neural network accelerator (159) according to an Artificial Neural Network (ANN) (125) involve different types of data that have different patterns of usages of the integrated image sensing device (101).

For example, making a prediction using the Artificial Neural Network (ANN) (125) includes the use of data specifying the model of the Artificial Neural Network (ANN) (125), input data provided to the artificial neurons, and output data generated by the artificial neurons.

The memory capacity of the integrated image sensing device (101) can be partitioned into different portions for the different types of ANN-related data. The different portions can be separately configured to optimize the access and storage of the corresponding data according to their patterns of usages by the neural network accelerator (159) and/or the processor(s) (133) of the computer system (131) in which the integrated image sensing device (101) is configured.

The model of the Artificial Neural Network (ANN) (125) can include the parameters specifying the static attributes of individual artificial neurons in the ANN (125) and the neuron connectivity in the ANN (125). The model data of the ANN (125) is static and does not change during the prediction calculation made using the ANN (125). Thus, the usage pattern of the model data is mostly read. However, the model data of the ANN (125) can change when an updated ANN (125) is installed. For example, the vehicle (111) can download an updated ANN (125) from the server (119) to the integrated image sensing device (101) of the vehicle (111) to update its prediction capability. The model data of the ANN (125) can also change during or after the training of the ANN (125) using a machine learning technique (e.g., 171 or 175). It is preferred to configure a memory separate partition or region of the integrated image sensing device (101) to store the model data, where the partition or region is operated according to configuration parameters that optimize the memory units for the specific usage patterns of the model data (e.g., mostly read, infrequent update). For example, when the memory units are implemented using a flash memory based on NAND logic gates, the memory units in the ANN model partition/region can be configured to operate in a Multi-Level Cell (MLC) mode, a Triple Level Cell (TLC) mode, or a Quad-Level Cell (QLC) mode, wherein each memory cells stores two, three, or four bits for increased storage capability.

Input data provided to the artificial neurons in the ANN (125) can include external inputs and internal inputs. The external inputs are generated typically by the sensors (e.g., 109) of the vehicle (111) but not by artificial neurons in the ANN (125). The external inputs can be saved in a cyclic fashion so that the input data of the most recent time period of a predetermined length of driving can be found in the integrated image sensing device (101). Thus, it is preferred to configure a separate memory partition or region of the integrated image sensing device (101) to store the external input data, where the partition or region is operated according to configuration parameters that optimize the memory units for the storage pattern of the external input data (e.g., enhanced endurance, cyclic overwrite). For example, when the memory units are implemented using a flash memory based on NAND logic gates, the memory units in the ANN input partition/region can be configured to operate in a Single Level Cell (SLC) mode, where each memory cell stores one bit of data for improved endurance in cyclic overwriting operations.

In some implementations, artificial neurons can have state variables that change over time in response to inputs during prediction calculations. For example, the activation level of a spiking neuron can change over time and is considered a dynamic state variable of the spiking neuron. In some implementations, such state variable data of artificial neurons has a similar storage usage pattern as the external input data; and thus, the state variable data can be stored in the partition or region configured for the external input data. In other implementations, the state variable data of artificial neurons is kept in a buffer and stored less frequently than the external inputs; and thus, another partition/region can be configured for storing the dynamic state variable data of artificial neurons.

Output data generated by the artificial neurons in the ANN (125) can be buffered for further access by the neural network accelerator (159) and/or the processor(s) (133) of the computer system (131). The output data can include external outputs and internal outputs. The external inputs are generated by artificial neurons as the output from the ANN (125), such as the results of classifications or predictions made by the ANN (125). The output of the ANN (125) is typically further processed by the processor(s) (133) of the computer system (131). The external inputs may be saved periodically (e.g., in a way similar to the storing of the state variable data). The internal outputs and/or some of the external outputs can be internal inputs to artificial neurons in the ANN (125). In general, it may not be necessary to store the internal outputs from the buffer of the data storage device to the memory components. In some implementations, when the buffer capability of the integrated image sensing device (101) is insufficient to hold the entire state variable data and/or the internal outputs, the integrated image sensing device (101) can use a swap partition/region to extend the capacity of the buffer. The swap partition/region can be configured for optimized random access and for improved endurance.

External outputs and/or dynamic states of neurons can be saved in a separate output partition or region, in a cyclic way so that the external output data and/or dynamic states of the neurons can be periodically stored, and the most recent sets of the external outputs and/or dynamic states can be found in the integrated image sensing device (101). External outputs and/or dynamic states of neurons can be stored selectively, since some of such data can be re-generated by the ANN from the external inputs stored in the input partition or region. Preferably, the output partition or region is configured to store one or more sets of external outputs and/or dynamic states that cannot be created from the external inputs stored in the input partition or region. In storing data in a cyclic way in an input/output partition or region, the oldest stored data sets are erased to make rooms for the most recent data sets. The ANN input/output partition/region can be configured for an optimized sequential write stream for copying data from the buffer of the data storage device into the memory units in the memory components of the data storage device.

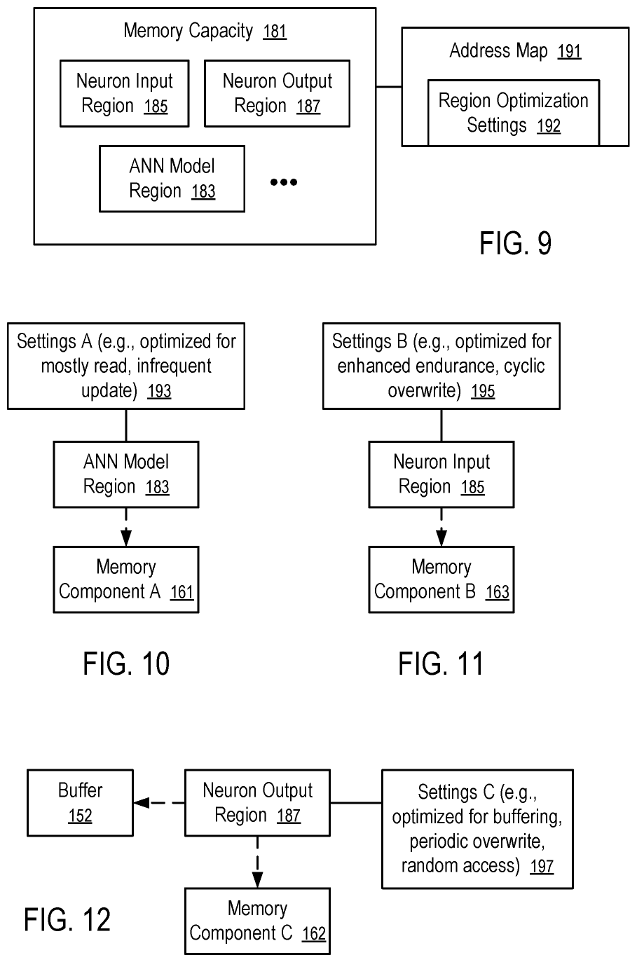

FIG. 9 shows a memory capacity (181) configured to support neural network computations according to one embodiment. For example, the memory capacity (181) of the memory components (161 to 163) of the integrated image sensing device (101) of FIG. 7 can be configured according to FIG. 9 to support neural network computations.

The storage capacity (181) of FIG. 9 can be implemented using a set of memory components (e.g., 161 to 163) of the integrated image sensing device (101).

A set of regions (183, 185, 187, . . . ) can be created on the storage capacity (181) of the integrated image sensing device (101). Each of the region (e.g., 183, 185, or 187) corresponds to a named portion of the storage capacity (181). Logical addresses are defined within each region. An address map (191) is configured to map between the logical addresses defined in the regions (183, 185, 187, . . . ) to the physical addresses of memory units in the memory components (e.g., 161 to 163 illustrated in FIG. 7).

The address map (191) can include region optimization settings (192) for the regions (183, 185, and 187).

For example, an ANN model region (183) can be a memory/storage partition configured for the model data of the Artificial Neural Network (ANN) (125). The region optimization settings (192) optimizes the memory operations in the ANN model region (183) according to the data usage pattern of ANN models (e.g., mostly read, infrequent update centric).

For example, a neuron input region (185) can be a memory/storage partition configured for the external input data to the Artificial Neural Network (ANN) (125). The region optimization settings (192) optimizes the memory operations in the neuron input region (185) according to the data usage pattern of the external input data (e.g., for enhanced endurance supporting cyclic overwrite of continuous input data flow for sequential writes).

For example, a neuron output region (187) can be a memory/storage partition/ configured for the external output data provided from the Artificial Neural Network (ANN) (125). The region optimization settings (192) optimizes the memory operations in the neuron output region (187) according to the data usage pattern of the external output data (e.g., improved endurance for periodically overwrite of data with random read/write access).

The integrated image sensing device (101) includes a buffer configured to store temporary/intermediate data of the Artificial Neural Network (ANN) (125), such as the internal inputs/outputs of the artificial neurons in the ANN (125).

Optionally, a swap region can be configured in the storage capacity (181) to extend the capacity of the buffer (152).

Optionally, the address map (191) includes a mapping between logic memory addresses received in the host interface (157) to access data of artificial neurons and the identities of the artificial neurons. Thus, a read or write command to access one type of data of an artificial neuron in one region can cause the controller 151 to access another type of data of the artificial neuron in another region.

For example, in response to a request to write external input data for a neuron into the storage capacity (181) of the data storage device (185), the address map (191) can be used to calculate the addresses of the model parameters of the neuron in the ANN model region (183) and read the model parameters into the buffer (152) to allow the neural network accelerator (159) to perform the computation of the output of the neuron. The output of the neuron can be saved in the buffer (152) as the internal input to other neurons (e.g., to reduce write amplification). Further, the identities of the other neurons connected to the neuron can also be retrieved from the ANN model region (183) into the buffer (152), which allows the neural network accelerator (159) and/or the processor to further process the propagation of the output in the ANN (125). The retrieval of the model data from the ANN model region (183) can be performed in parallel with the storing of the external input data into the neuron input region (185). Thus, the processors (133) of the computer system (131) of the vehicle (111) do not have to explicitly send in read commands for the retrieval of the model data from the ANN model region (183).

Similarly, in response to reading output data of a neuron, the address map (191) can be used to compute the addresses of the model parameters of the neuron stored in the ANN model region (183) and read the model parameters into the buffer (152) to allow the neural network accelerator (159) to apply internal inputs in the buffer (152) to the perform the computation of the output of the neuron. The computed output can be provided as a response to the reading of the output data for the neuron, without the integrated image sensing device (101) having to store the output data in the memory components (e.g., 161 to 163). Thus, the processors (133) and/or the neural network accelerator (159) can control the computations of the neuron via writing inputs to neurons and/or reading outputs from neurons.

In general, incoming external input data to the ANN (125) can be raw sensor data (121) generated directly by the sensors (e.g., 109) without processing by the processors (133) and/or the neural network accelerator (159). Alternatively, indirect sensor data (121) that has processed by the processors (133) for the ANN (125) from the signals from the sensors (101) can be provided as the external input data. The incoming external input data can be accepted in the host interface (157) and written in a cyclic way into the neuron input region (185), and automatically buffered in the buffer (152) for neural network accelerator (159) to generate neuron outputs using the model stored in the ANN model region (183). The outputs generated by the neural network accelerator (159) can be further buffered as internal inputs for further application of the model in the ANN model region (183). When the external outputs become available, the integrated image sensing device (101) can report the completion of the write requests with an indication of the availability of the external outputs. Optionally, the controller 151 and/or the neural network accelerator (159) can generate internal read commands to propagate signals in the ANN (125) in generating the external outputs. Alternatively, the host processors (133) can control the propagation of signals in the ANN (125) by selectively reading outputs of neurons; and the integrated image sensing device (101) can actively buffer data that may be needed in the buffer (152) to accelerate the ANN computation.

FIG. 10 illustrates the configuration of a memory region (183) for an Artificial Neural Network (ANN) model according to one embodiment. For example, the configuration of FIG. 10 can be implemented in the integrated image sensing device (101) of FIG. 7 with a logical memory capacity (181) of FIG. 9. For example, the settings (193) of FIG. 10 can be part of the region optimization settings (192) of FIG. 9.

The configuration of FIG. 10 maps an ANN model region (183) to at least one memory component A (161). Preferably, the at least one memory component A (161) can be used by the controller (151) in parallel with memory components (e.g., 163) that hosts the other regions (e.g., 185 and 187) of ANN data. For example, the memory component A (161) can be in an integrated circuit package that is separate from the integrated circuit packages for the other regions (e.g., 185 and 187). Alternatively, the memory components (161 to 163) are formed on separate integrated circuit dies embedded in a same integrated circuit package. Alternatively, the memory components (161 to 163) can be formed on separate regions of an integrated circuit die, where the separate regions can be operated substantially in parallel (e.g., for read, for erase, and/or for write).

In FIG. 10, the settings (197) are optimized to the usage pattern of mostly read and infrequent update.

FIG. 11 illustrates the configuration of a region (185) for the inputs to artificial neurons according to one embodiment. For example, the configuration of FIG. 10 can be implemented in the integrated image sensing device (101) illustrated in FIGS. 7 and/or 9. For example, the settings (195) of FIG. 10 can be part of the region optimization settings (192) of FIG. 9.

The configuration of FIG. 11 maps a neuron input region (185) to at least one memory component B (163). Preferably, the at least one memory component B (163) can be used by the controller (151) in parallel with memory components (e.g., 161) that hosts the other regions (e.g., 183 and 187) of ANN data. For example, the memory component B (163) can be in an integrated circuit package that is separate from the integrated circuit packages for the other regions (e.g., 183 and 187). Alternatively, the memory components (161 to 163) are formed on separate integrated circuit dies embedded in a same integrated circuit package. Alternatively, the memory components (161 to 163) can be formed on separate regions of an integrated circuit die, where the separate regions can be operated substantially in parallel (e.g., for read, for erase, and/or for write).

In FIG. 11, the settings (197) are optimized to the usage pattern of enhanced endurance in cyclic sequential overwrite in recording a continuous stream of input data that is sampled at a fixed time interval.

FIG. 12 illustrates the configuration of a region (187) for the outputs from artificial neurons according to one embodiment. For example, the configuration of FIG. 10 can be implemented in the integrated image sensing device (101) illustrated in FIGS. 7 and/or 9. For example, the settings (197) of FIG. 10 can be part of the region optimization settings (192) of FIG. 9.

The configuration of FIG. 12 maps a neuron output region (187) to at least one memory component C (162). Preferably, the at least one memory component C (162) can be used by the controller (151) in parallel with memory components (e.g., 161 and 163) that hosts the other regions (e.g., 183 and 185) of ANN data. For example, the memory component C (162) can be in an integrated circuit package that is separate from the integrated circuit packages for the other regions (e.g., 183 and 185). Alternatively, the memory components (161 to 163) are formed on separate integrated circuit dies embedded in a same integrated circuit package. Alternatively, the memory components (161 to 163) can be formed on separate regions of an integrated circuit die, where the separate regions can be operated substantially in parallel (e.g., for read, for erase, and/or for write).

In FIG. 12, the settings (197) are optimized to the usage pattern of buffered data for periodic overwrite with random access. For example, memory units are configured via the optimization settings (193 to 197) to update/overwrite in the neuron output region (187) at a frequency higher than in the ANN model region (183), but lower than in the neuron input region (185).

A communication protocol/interface can be configured to allow an integrated image sensing device to perform neural network acceleration on the fly with reduced data traffic to the host system (104).

For example, the host processor (e.g., 133) of a vehicle (111) can provide write commands to the integrated image sensing device (101) to store the model of an artificial neural network in a model partition (e.g., 183).

To use the ANN model in classifications and/or predictions, the host processor (e.g., 133) of a vehicle (111) can optionally stream input data for the ANN (125) into the neuron input partition (e.g., 185). The neural network accelerator (159) of the storage device (112) can automatically apply the images from the image sensor (109) and, if there is any, the input data from the host processor (133) to the model stored in ANN model partition (e.g., 183) in accordance with the address map (191). The integrated image sensing device (101) makes the computed outputs available for propagation in the ANN (125). Preferably, the computed outputs are made available to the neural network accelerator (159) through the buffer (152) without the need to store the intermediate outputs into memory components (e.g., 161 to 163). Thus, the data communications between the host processor (e.g., 133) and the integrated image sensing device (101) for the transporting of outputs of neurons can be reduced. When the outputs have propagated to the output neurons in the ANN (125), the integrated image sensing device (101) can provide a response to a request from the host processor (e.g., 133). The response indicates that the external output from neurons in the ANN (125) is available. In response, the host processor (e.g., 133) of a vehicle (111) can optionally issue read commands to retrieve the external outputs for further processing.

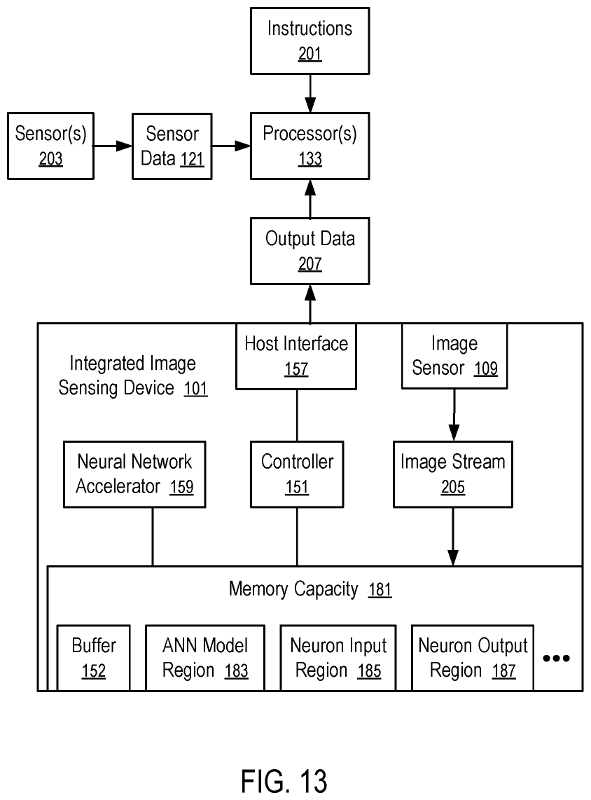

FIG. 13 shows communications between a host system (e.g., 104) and an integrated image sensing device (101) according to one embodiment. For example, the communications as illustrated in FIG. 13 can be implemented in the vehicle (111) of FIG. 2 or 3, with an integrated image sensing device (101) illustrated in FIG. 1, or 7.

In FIG. 13, the processor(s) (133) of the host system (e.g., 104) can be configured with a simplified set of instructions (201) to perform neural network computation, since some of the computations involving the ANN (125) is performed by the neural network accelerator (159) within the integrated image sensing device (101). It is not necessary to transport the image stream (205) and the model data back to the processor(s) (133) during the use of the ANN (125) for predictions and/or classifications.

The image sensor (109) can generate a continuous image stream (205) as part of sensor data (121) for the vehicle (111). The images in the stream (205) can be generated at a fixed, predetermined time interval (e.g., during the operation of the vehicle (111)).

The image stream (205) is applied to input neurons in the ANN (125). Input neurons in the ANN (125) are configured to accept external inputs to the ANN (125); and output neurons are configured to provide external outputs from the ANN (125).

Optionally, the vehicle (111) can have further sensor(s) (203) configured to generate sensor data (121).

The processor(s) (133) can execute the instructions (201) to process the output data (207) from the integrated image sensing device (101) and the sensor data (121).

Optionally, the processor(s) (133) can write the sensor data (121) into the neuron input region (185) to obtain the output data (207) that is based on both the sensor data (121) and the image stream (205).

The integrated image sensing device (101) stores the image stream (205) (and optionally the sensor data (121)) into the neuron input region (185) in a cyclic way where the oldest input set corresponding to the oldest time instance of data sampling for data sets currently stored in the neuron input region (185) is erased to store the newest set of inputs.

For each input data set, the neural network accelerator (159) applies the model of the ANN (125) stored in the ANN model region (183). The neural network accelerator (159) (or the processor(s) (133)) can control the propagation of signals within the neural network. When the output neurons of the ANN (125) generate their outputs responsive to the input data set, the integrated image sensing device (101) can provide to the processor (133) an indication that the neuron output are ready for retrieval. The indication can be configured in a response to the request from the processor(s) (133) to write the input data set into the neuron input region (185). The processor(s) (133) can optionally retrieve the output data (207) (e.g., in accordance with conditions and/or criteria programmed in the instructions).

In some embodiments, a trigger parameter is configured in the integrated image sensing device (101). When an output parameter in the external output (217) meetings a requirement specified by the trigger parameter, the data storage device provides the response to the request from the processor(s) (133) to write the input data set into the neuron input region (185).

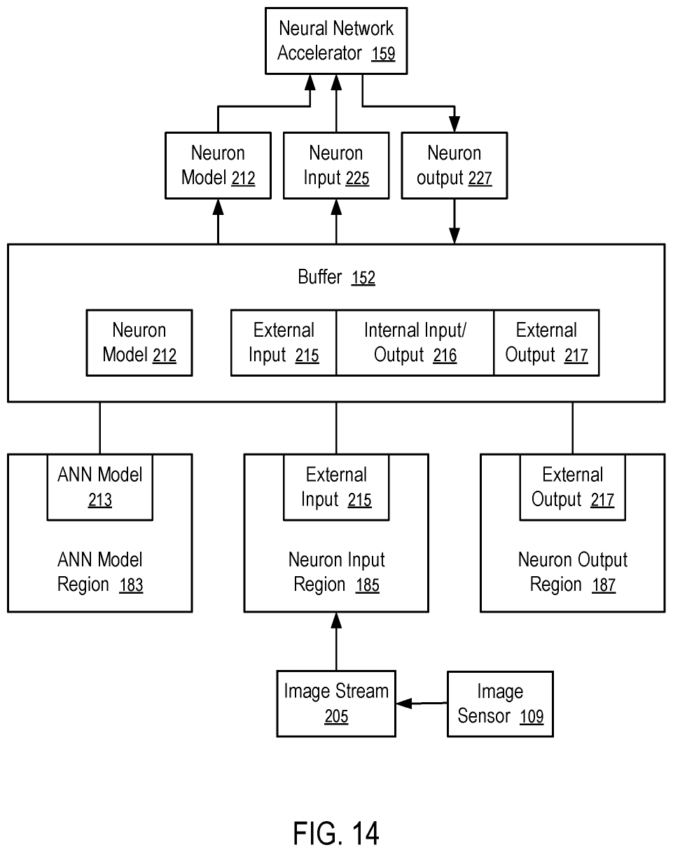

FIG. 14 shows communications within an integrated image sensing device (101) according to one embodiment. For example, the communications of FIG. 14 can be implemented an integrated image sensing device (101) illustrated in FIG. 1 or 7, in connection with the communications with the host system (104) as illustrated in FIG. 1.

In FIG. 14, the model region (183) stores the model (213) of an ANN (125). In response to receiving a set of external input (215) for a time instance from the input stream (205) in the buffer (152), the integrated image sensing device (101) can write the external input (215) into the input region (185) in parallel with retrieving a neuron model (212) containing a portion of the ANN model (213) corresponding to the parameters of the input neurons and/or the identities of neurons connected to the input neurons. The buffer (152) allows the neural network accelerator (159) to combine the neuron model (212) and the external input (225) to generate the output (227) of the input neurons.

In general, the neuron output (227) can include a portion that is the internal output (216) for further propagation within the ANN (125) and/or a portion that is the external output (217) for the processor(s) (133).

The internal output (216) is stored in the buffer (152) as internal input (216) for further propagation in the ANN (125) in a way similar to the generation of neuron outputs (227) from the external input (215). For example, a portion of the internal input (216) can cause the controller (151) and/or the neural network accelerator (159) to retrieve corresponding neuron model (212) relevant to the internal input such that the internal input is applied in the neural network accelerator (159) to the corresponding neuron model (212) to generate their neuron outputs (227).

When the complete set of external output (217) is available in the buffer (152), the external output (217) can be stored into the output region (187).

Optionally, the storage device (112) does not store each set of external output (217) corresponding to a set of stored external input (215) sampled at a time instance. For example, the storage device (112) can be configured to store one set of external output (217) every time when a predetermined number of sets of external input (e.g., 215) has been counted. Alternatively, or in combination, the processor(s) (133) can determine whether or not to store the external output (217). For example, the storage device (112) can be configured to store the external output (217) in response to the processor(s) (133) retrieving the external output (217) for further processing. For example, the storage device (112) can be configured to store the external output (217) in response to a write command from the processor(s) (133) after the processing of the external output (217) in the processor(s) (133).

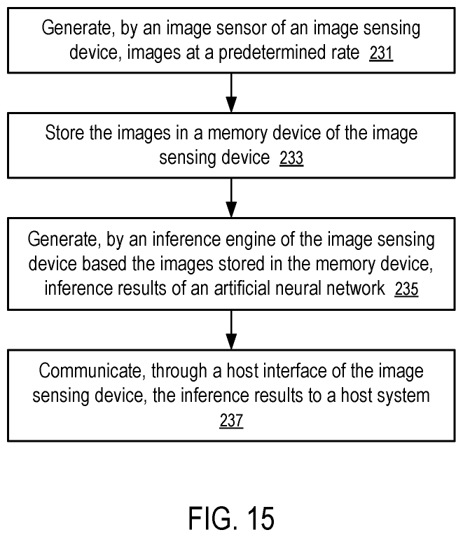

FIG. 15 shows a method implemented in an integrated image sensing device according to one embodiment. For example, the method of FIG. 15 can be implemented in an integrated image sensing device (101) of FIG. 1 or 7 in connection with a host system (104) of FIG. 1 or a computer system (131) or ADAS (105) of FIG. 3 in a vehicle (111) of FIG. 2 or 3.

At block 231, an image sensor (109) of an image sensing device (101) generates images at a predetermined rate.

At block 233, the images are stored in a memory device (107) of the image sensing device (101).

At block 235, an inference engine (108) of the image sensing device (101) generates, based the images stored in the memory device (107), inference results of an artificial neural network (125).

At block 237, the inference results are communicated to a host system (e.g., 104, 131) through a host interface (106 or 157) of the image sensing device (101).

Since the data size of the inference results is much smaller than the data size of the corresponding images, the predetermined rate of images generated by the image sensor (103) can exceed a communication bandwidth between the image sensing device (101) and the host system (e.g., 104, 131).

Optionally, the image sensing device (101) can receive sensor data (121) through the host interface (106 or 157) from the host system (e.g., 104 or 131). The inference results can be generated based on both the sensor data from the host system (e.g., 104, 131) and the images from the image sensor (109).

Optionally, the host system (e.g., 104 or 131) can request the image sensing device (101) to transmit one or more images corresponding to selected inference results that are generated from the requested images. The selected images can be portions of original images generated by the image sensor, or images with reduced resolution in certain areas, or the original images from the image sensor (109).

The image sensor (109) can generate images and store the images into a predefined portion of the memory device cyclically by replacing an oldest image stored in the portion with a newest image generated by the image sensor (109).

The image sensor (109) can be formed on a first integrated circuit die; and the memory units of the memory device (107) and the logic circuits of the inference engine (108) can be formed on one or more second integrated circuit dies. The one or more second integrated circuit dies can be stacked on the first integrated circuit die to form a three dimensional integrated circuit (3D IC). In the 3D IC, the one or more second integrated circuit dies can be connected to the first integrated circuit die by Through-Silicon Vias (TSVs) to provide high communication bandwidth among the image sensor (109), the memory device (107) and the inference engine (108) (e.g., higher than the communication bandwidth of the host interface (e.g., 106 or 157).

Optionally, the 3D IC can include a host/communication interface (106, 157) of a ball grid array solid state drive (BGA SSD) and be configured as one integrated circuit package. For example, the host/communication interface (106, 157) can be configured to communicate in accordance with a serial communication protocol, such as a protocol in accordance with a standard for a Peripheral Component Interconnect express (PCIe) bus, a Serial Advanced Technology Attachment (SATA) bus, or a Universal Serial Bus (USB) bus.

For example, the host interface (106, 157) can be configured to receive commands to store sensor data into a portion of the memory units of the memory device (107) of the integrated image sensing device (101); and in response, the inference engine (108) can be configured to generate inference results based on applying, to the artificial neural network (125), both the sensor data received via the host interface (106, 157) and the images generated by the image sensor (109).

In a typical operation, the inference engine (108) is configured to process the images from the image sensor (109) according to an artificial neural network (125) and generate inference results as output (207) of the image sensing device (101).

Optionally, the logic circuits of the inference engine (108) include a neural network accelerator (159) configured to perform matrix arithmetic computations for data stored in the memory units. For example, the matrix arithmetic computations can include matrix multiplication and accumulation operations.

For example, the image sensing device (101) can be configured in a vehicle (111) having an advanced driver assistance system (105) connected to the host/communication interface (106, 157) of the image sensing device through a communication connection. At least a portion of an artificial neural network (125) of the advanced driver assistance system (105) can be implemented in the image sensing device (101) using the inference engine (108). For example, the inference engine (108) can be configured to process images from the image sensor (109) and generate inference results that are communicated through the communication connection to the advanced driver assistance system (105). The inference engine (108) can processes the images generated by the image sensor (109) at a rate that exceeds the communication bandwidth of the communication connection from the host/communication interface (106, 157) to the advanced driver assistance system (105).

Optionally, the vehicle (111) can have one or more sensors that are separate from the image sensing device. The sensor data from the one or more sensors can be written into the image sensing device (101) via the communication connection to generate the inference results based on both the sensor data and the images. The inference results can be further processed by the advanced driver assistance system (105) to generate input signals for a control for steering (141), braking (143), or acceleration (145), or any combination thereof.

The server (119), the computer system (131), the host system (104), the data storage device (112), and/or the integrated image sensing device (101) can each be implemented as one or more data processing systems.

Various additional embodiments related to image sensors stacked with a memory device that uses an inference engine to reduce data transmission to a host system are now described below. The generality of the following description is not limited by the various embodiments described above.

At least some embodiments below relate to a sensing device that is stacked with a memory device. The memory device may store sensor data and results from processing the sensor data that are used by a host system (e.g., a computing device of an autonomous vehicle, or a computing device that accesses data stored in the memory device). The memory device processes the sensor data as input to an ANN, and sends output from the ANN to the host system. In one example, the memory device is a solid state drive mounted in an electric vehicle, and the host system is a controller of a vehicle component (e.g., a braking system). The vehicle may be, for example, a car, plane, drone, satellite, or spacecraft.

In prior sensing systems, sensor data is typically sent to a central processing unit (CPU) for processing. Data from an image sensor, for example, may be generated at millions of pixels per frame and several frames per second. This amount of data per sensor, multiplied by the number of sensors in the system, can overwhelm the bandwidth of communication links between the sensors and the CPU, and can overwhelm the ability of the CPU to process the data. This may result in a reduced frame rate from the image sensors. Also, it is sometimes difficult for systems to accurately draw inferences from sensor data (e.g., from image data under low light conditions) resulting in reduced system accuracy and reliability.

Various embodiments described below address the above technical problems by providing a sensing device (e.g., an image sensor) that includes a memory device with neural networking capability and a neural network accelerator. The memory device can perform machine learning analytic functions (e.g., image classification, object detection, pixel segmentation, etc.) on the sensor data. In one example, the memory device is a neuromorphic memory device (e.g., a memory device that performs multiply and accumulate operations and is stacked with a camera semiconductor chip) that accelerates machine learning operations. Processing the sensor data within the sensor may reduce the amount of data transmitted to the CPU and reduce the processing load on the CPU. This may free up CPU processing power for other tasks and enable higher analytics capabilities while consuming less power.

In one example, image sensor(s) of a sensing system are used in a camera (e.g., a camera used in automotive or other applications) that generates millions of pixels per frame, and several frames per second. The memory device includes a built-in neural network capability (e.g., native logic or CMOS under array that is stacked with the image sensor(s)) for processing the data as it is captured, and sending only post-processed information upstream (e.g., to a host controller of an automobile).

In one embodiment, a sensing system includes an image sensor that generates image data. The system includes a neuromorphic memory device that stores the generated image data, and a host interface to communicate with a host system (e.g., an edge server of a vehicle). The memory device is stacked with the image sensor (e.g., encapsulated in a packaged device, or formed on a semiconductor die). The memory device includes an inference engine to generate inference results using the stored image data as input to an artificial neural network (ANN). The inference engine includes a neural network accelerator configured to perform matrix arithmetic computations on data stored in the memory device. The host interface sends the inference results to the host system for processing. In one example, the neural network accelerator includes a memristor crossbar array configured to perform the matrix arithmetic computations.

In one embodiment, analytics are performed near an image sensor to reduce data traffic to a main system on chip (SOC). The analytics are performed using machine learning (ML) capabilities with a neuromorphic memory device and an inference engine stacked with the image sensor. The neuromorphic memory device performs analytics at the sensor to reduce traffic upstream enabling higher frames per second. For example, this enables ADAS/autonomous systems that provide higher analytics capability for lower power. In one example, the image sensors are used in cameras for automotive and other applications and generate at least millions of pixels per frame and several frames per second.

The neuromorphic memory device uses neural network analytics stacked with the image sensor for processing the data from the cameras as it is captured, and sending only post-processed data or information upstream. For example, this enables a central CPU and/or GPU of the system to perform other critical parameters (e.g., other vehicle functions like navigation or other control) instead of processing the captured camera data. Some advantages of this approach include increased frames per second bandwidth/processing (e.g., higher frames per second), and lower power and cost. In one example, the neuromorphic memory device is capable of performing several machine learning analytics such as image classification, object detection, and/or pixel segmentation (e.g., as used in ADAS/autonomous systems).

At least some embodiments described below provide redundant sensors, which may improve system accuracy and reliability. In one embodiment, a system includes two cameras. Each camera generates an inference result using an ANN. The system further includes a non-image sensing device (e.g. lidar, radar, or microphone) or a storage device (e.g., neuromorphic memory) configured to generate an inference result (e.g., using a SNN). Each camera, and the sensing device or storage device communicates respective inference results to a processing device or logic circuit. The processing device or logic circuit includes a majority voter that provides an output to a host system. The inference results from the cameras and the sensing device or storage device are input to the majority voter. In one example, an output from the majority voter is used to control a function of a vehicle.

In one embodiment, a sensor data processing system uses redundant artificial intelligence (Al) computation for an autonomous vehicle. The autonomous vehicle can include multiple AI-capable devices, such as cameras with ANN processing logic, storage devices with Al accelerators, etc. The autonomous vehicle can distribute partial processing results to the different AI-capable devices to generate redundant results for improved reliability. For example, the image stream generated in a first camera can be processed by ANN processing logic in the first camera to generate first neuron outputs. The image stream generated in a second camera can be processed by ANN processing logic in the second camera to generate second neuron outputs.

The first neuron outputs can be provided to the second camera for combination with the second neuron outputs in a further layer of neurons in the second camera. The second neuron outputs can be provided to the first camera for combination with the first neuron outputs in a corresponding further layer of neurons in the first camera. Thereby, the first and second cameras generate redundant outputs based on the image stream generated in the first camera and the image stream generated in the second camera. The autonomous vehicle uses the outputs only when the redundant outputs agree with each other (e.g., agreement determined by logical, statistical, and correlation matching, such as within a predetermined threshold). When there are more than two redundant outputs, a majority voter can be used to select an output used by the autonomous vehicle. The redundancy improves the reliability of the vehicle.

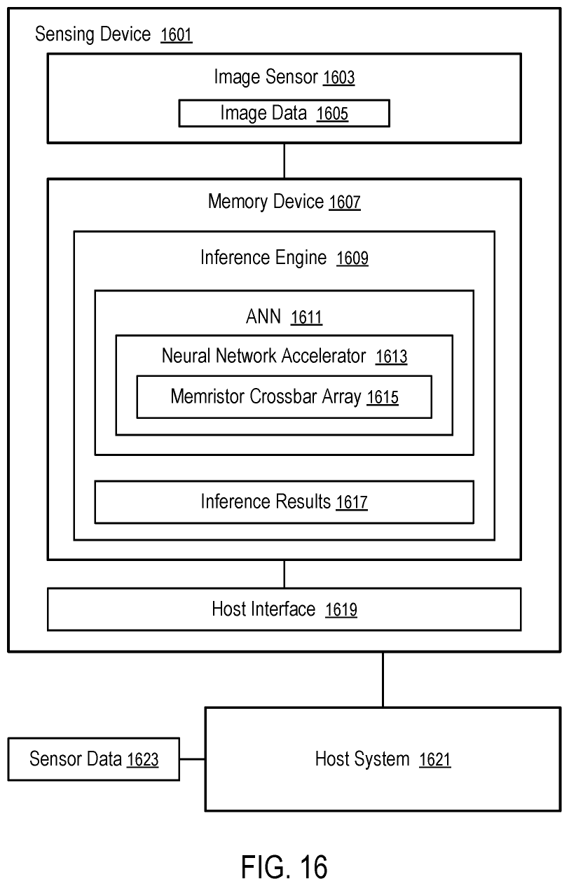

FIG. 16 shows a sensing device (1601) that includes a memory device (1607) with a neural network accelerator (1613), according to one embodiment. Sensing device (1601) includes image sensor (1603), memory device (1607), and host interface 1619. Data from image sensor (1603) (e.g., image data 1605) is stored and processed in memory device (1607) and the results (e.g., inference results 1617) are output on host interface (1619).

Image sensor (1603) provides image data (1605). Image sensor (1603) may be, for example, an integrated circuit chip image sensor, a camera module, radar sensor, sonar sensor, thermal image sensor, multi-spectral image sensor or other type of image sensor. Image sensor (1603) may be manufactured using various technologies (e.g., a charge-coupled device (CCD) image sensor, active-pixel image sensor (CMOS sensor), quanta image sensor (QIS), etc.). In one example, image sensor (1603) is a camera module embedded within sensing device (1601). Image data (1605) may include, for example, still images, video clips, streaming video or other types of image data. Image data (1605) may be delivered as discrete packets of data, as streaming data, or other type of data format.

Memory device (1607) is stacked with image sensor (1603) in sensing device (1601). Memory device (1607) can include volatile memory (e.g., DRAM and/or SRAM), non-volatile memory (e.g., SLC, MLC, TLC, QLC flash memory, cross point memory, neuromorphic memory, RRAM, etc.), or any combination of volatile and non-volatile memories.

Examples of non-volatile memory include flash memory, memory units formed based on negative-and (NAND) logic gates, negative-or (NOR) logic gates, Phase-Change Memory (PCM), magnetic memory (MRAM), resistive random-access memory (RRAM), cross point memory and other memory devices. A cross point memory device can use transistor-less memory elements, each of which has a memory cell and a selector that are stacked together as a column. Memory element columns are connected via two lays of wires running in perpendicular directions, where wires of one lay run in one direction in the layer located above the memory element columns, and wires of the other lay is in another direction and in the layer located below the memory element columns. Each memory element can be individually selected at a cross point of one wire on each of the two layers. Cross point memory devices are fast and non-volatile and can be used as a unified memory pool for processing and storage. Further examples of non-volatile memory include Read-Only Memory (ROM), Programmable Read-Only Memory (PROM), Erasable Programmable Read-Only Memory (EPROM) and Electronically Erasable Programmable Read-Only Memory (EEPROM), etc. Examples of volatile memory include Dynamic Random-Access Memory (DRAM) and Static Random-Access Memory (SRAM).

Memory device (1607) may be provided in various forms including, for example, one or more die stacked and packaged with other integrated circuit components, soldered to a printed circuit board, NVMe module, or other form factor.

Memory device (1607) may include an embedded processing device or may be stacked with a processing device in sensing device (1601). In one example, logic circuits are incorporated into memory device (1607) using CMOS under array technology or other technology for incorporating logic circuits within a memory integrated circuit die.

Memory device (1607) includes an inference engine (e.g., inference engine 1609). Inference engine (1609) receives input data (e.g., image data 1605 stored in memory device 1607), processes the input data, and generates inference results (e.g., inference results 1617) as output. Inference engine (1609) processes the input data using an artificial neural network (ANN) (e.g., ANN 1611). In one example, ANN (1611) may be a portion of a larger ANN (e.g., another portion of the larger ANN may be stored on host system 1621). In one example, data (1605) is sonar data from a sonar sensor. Inference results (1617) may be identification of the distance of an object from the sonar sensor.

Inference engine (1609) includes a neural network accelerator (e.g., neural network accelerator 1613) configured to perform matrix arithmetic computations on data stored in memory device (1607). Neural network accelerator (1613) is hardware that may speed up neural network functions. In one example, neural network accelerator (1613) performs at least a portion of computations of ANN (1611) using image data (1605) as input.

Neural network accelerator (1613) can be configured to perform computations, such as matrix arithmetic computations for an ANN and/or or differential equation simulations for an SNN, using data stored in memory device (1607).

Examples of matrix arithmetic computations include matrix multiplication and accumulation operations. After a computation to generate a result of the matrix arithmetic computations (e.g., inference results 1617), neural network accelerator (1613) can provide the result as an output (e.g., in response to a read command) of inference engine (1609). Alternatively, or in combination, the result of the matrix arithmetic computation can be buffered as an operand for a next matrix computation.

When ANN (1611) includes a Spiking Neural Network (SNN), neural network accelerator (1613) can be configured to simulate a differential equation controlling activation levels of neurons in the SNN. Optionally, memory device (1607) is configured to store states of the neurons in the spiking neural network according to a predetermined pattern; and the neural network accelerator is configured to automatically update the states of the neurons over time according to the differential equation. For example, neural network accelerator (1613) can be configured to train the SNN via unsupervised machine learning to detect anomaly. In one example, ANN (1611) is a spiking neural network.

In one example, neural network accelerator (1613) is included within an integrated circuit die of memory device (1607). In one example, neural network accelerator (1613) is located on a separate integrated circuit die electrically connected to memory device (1607). In one example, image sensor (1603) is included in an integrated circuit die that is stacked on top of the die of memory device (1607).

In one embodiment, neural network accelerator (1613) includes a memristor crossbar array (e.g., memristor crossbar array 1615) configured to perform matrix arithmetic computations (e.g., matrix multiplication and accumulation operations).

In general, a memristor is a two-terminal electrical component that has a non-constant electrical resistance. Its resistance can change based on the history of current flowing through the memristor and/or the history of voltage applied on the memristor. In general, a memristor crossbar array is an array of memristors where each memristor is located at the intersection of a wordline and a bitline. A crossbar array of memristors can be configured to perform Multiply-and-Accumulate (MAC) operations via analog circuitry. Electric currents going through the wordlines through a set of memristors in the crossbar array to a bitline are summed in the bitline, which corresponds to the accumulation operation. The electric currents correspond to the multiplication of the voltages applied on the wordlines and parameters associated with the resistances of the memristors, which corresponds to the multiplication operations.

In one example, the parameters associated with the resistances of the memristors represent neurons in ANN (1611), where the neuron weights are implemented as programmed resistances in the memristors of the memristor crossbar array (1615). In one example, stored image data (1605) is input to memristor crossbar array (1615) (e.g., as voltages applied to wordlines). In one example, memristor crossbar array (1615) performs MAC operations by converting voltages on the wordlines to currents on the bitlines.

In one embodiment, memory device (1607) is a neuromorphic memory device. In general, a neuromorphic memory device is a memory device that implements neural network analytic capabilities (e.g., multiply and accumulate operations). In one example, memory device (1607) is a neuromorphic memory device implemented using a memristor crossbar array (e.g., memristor crossbar array 1615). In one example, memory device (1607) receives image data (1605) from image sensor (1603). Memory device (1607) uses memristor crossbar array (1615) to process image data (1605) and generate inference results (1617) (e.g., pixel segmentation of image data 1605).

Sensing device (1601) includes a host interface (e.g., host interface 1619). Host interface (1619) can be used as a communication link to transfer data and/or commands between sensing device (1601) and a host system (e.g., host system 1621). In one example, host interface (1619) sends inference results (1617) to host system (1621) for further processing. Host interface (1619) may be, for example, a wireless or a wired interface.

Host interface (1619) may be in accordance with a standardized communication protocol or may be implemented in a proprietary protocol. A wired interface, may be, for example, in accordance with a communication protocol for Peripheral Component Interconnect express (PCIe), Serial Advanced Technology Attachment (SATA), Serial Attached SCSI (SAS), Universal Serial Bus (USB), Storage Area Network (SAN), Ethernet, and/or an IEEE-1394 bus, etc. A wireless interface, for example, may be in accordance with a communication protocol such as Bluetooth, a mobile wireless network such as 4G or 5G, a local area network (LAN), a wide area network (WAN), an intranet, an extranet, the Internet, and/or any combination thereof.

Host interface (1619) connects sensing device (1601) with host system (1621). In one example, host system (1621) coordinates the actions of components (e.g., sensing device 1601 and other components) within a larger system. Host system (1621) may be, for example, a computer, embedded computer, server, cloud server, edge server, laptop, tablet, smartphone, or other electronic device controlled by a processing device.

In one example, sensing device (1601) receives sensor data (e.g., sensor data 1623) through host interface (1619) from host system (1621). Inference engine (1609) is configured to generate inference results (1617) using sensor data (1623) as additional input to ANN (1611). In one example, sensor data (1623) is vibration data from a vibration sensor on an assembly line. Sensing device (1601) may be a camera monitoring video images of the assembly line. Sensing device (1601) may combine image data (1605) and sensor data (1623) as input to inference engine (1609) to monitor the assembly line for anomalies.

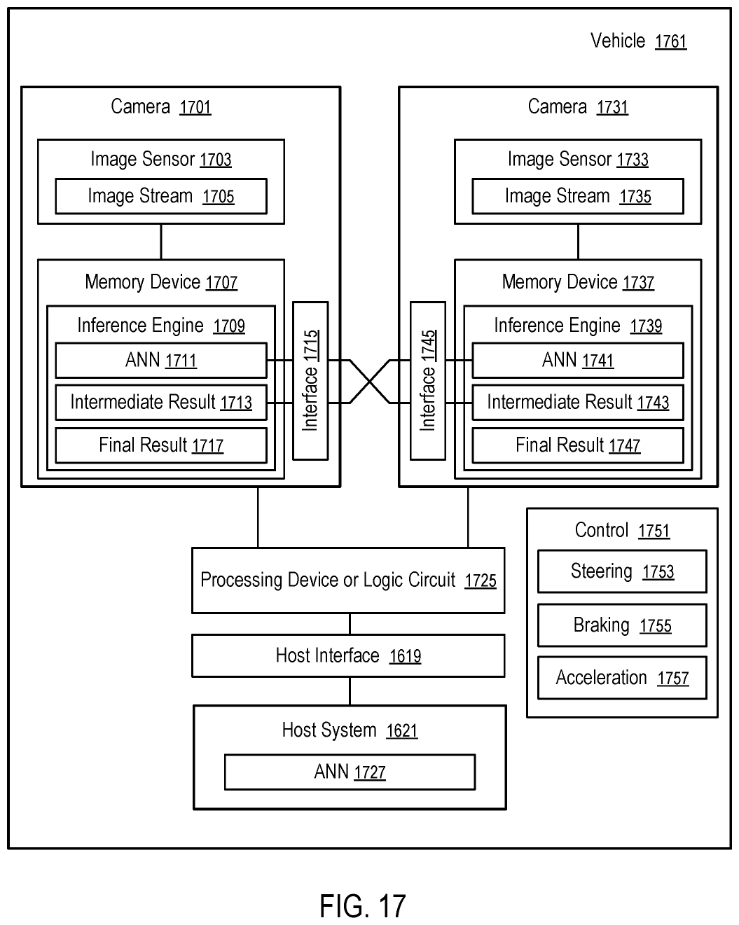

FIG. 17 shows a system having a vehicle configured to collect and process sensor data from redundant sensors according to one embodiment. The vehicle includes a processing device or logic circuit and redundant cameras, with each camera including an inference engine. The inference engines within each of the cameras process image streams and generate intermediate results. The intermediate result from each camera is sent to each redundant camera, and each camera uses the intermediate results from both cameras to generate final results from each camera. The processing device or logic circuit compares the final results from each camera and sends a final result output to a host system if the final results from both cameras match (e.g., match within a predetermined threshold quantity, percentage, or correlation).

The vehicle (e.g., vehicle 1761) may be, for example, an autonomous vehicle, a drone, an electric vehicle, a gasoline or diesel-powered vehicle, or other vehicle. Vehicle (1761) may be a land operated vehicle, watercraft, aircraft, or other type of vehicle.

In one embodiment, vehicle (1761) includes cameras (e.g., cameras 1701, 1731). Cameras (1701, 1731) may be, for example, digital cameras, video cameras, dashcams, omnidirectional cameras, onboard cameras, infrared cameras, rangefinder cameras, ultrasonic cameras, etc. Each of the cameras (1701, 1731) include an image sensor (e.g., image sensors 1703, 1733), and memory devices (e.g., memory devices 1707, 1737). In one example, cameras (1701, 1731) are embodiments of sensing device (1601) of FIG. 16. In one example, image sensors (1703, 1733) generate image streams (e.g., image streams 1705, 1735).

In one example, cameras (1701, 1731) include memory devices (e.g., memory devices 1707, 1737). In one example, memory devices (1707, 1737) are similar to memory device (1607) of FIG. 16.

In one embodiment, memory devices (1707, 1737) include inference engines (e.g., inference engines 1709, 1739) and ANNs (e.g., ANNs 1711, 1741). Inference engine (1709) receives image stream (1705) as input to a first portion of ANN (1711) and processes the image stream to generate an intermediate result (e.g., intermediate result 1713). Inference engine (1739) receives image stream (1735) as input to a first portion of ANN (1741) and processes the image stream to generate an intermediate result (e.g., intermediate result 1743). In one example, cameras (1701, 1731) are video cameras of vehicle (1761), and vehicle (1761) is an autonomous vehicle. Intermediate results (1713, 1743) may represent objects identified in image streams (1705, 1735).

Cameras (1701, 1731) include interfaces (e.g., interfaces 1715, 1745). In one embodiment, interface (1715) communicates intermediate result (1713) to camera (1731) and interface (1745) communicates intermediate result (1743) to camera (1701). Interfaces (1715, 1745) may be, for example, wired or wireless interfaces. In one example, interfaces (1715, 1745) are in the form of a standardized interface. Interfaces (1715, 1745) may be, for example, compliant with Peripheral Component Interconnect express (PCIe), Universal Serial Bus (USB), Ethernet, Serial Advanced Technology Attachment (SATA), Serial Attached SCSI (SAS), Firewire or other interface protocol. In one example, interfaces (1715, 1745) are vendor proprietary interfaces.

In one embodiment, inference engine (1709) uses intermediate result (1713) and intermediate result (1743) as input to a second portion of ANN (1711) and generates a final result (e.g., final result 1717). Inference engine (1739) uses intermediate result (1713) and intermediate result (1743) as input to a second portion of ANN (1741) and generates a final result (e.g., final result 1747).

In one example, ANN (1711) includes a different neuron model than ANN (1741). For example, the neuron model for ANN (1711) may be optimized for processing images generated in low-light conditions, and the neuron model for ANN (1741) may be optimized for processing images generated in bright-light conditions.

In one example, vehicle (1761) includes a processing device or logic circuit (e.g., processing device or logic circuit 1725) configured to communicate with cameras (1701, 1731). Processing device or logic circuit (1725) may be, for example, a microprocessor, graphics processor, embedded processor, embedded controller, central processing unit (CPU), system on a chip (SOC), application specific integrated circuit (ASIC), field programmable gate array (FPGA), or other processing device. Processing device or logic circuit (1725) may be composed of a single processor with a single processing core, a single processor with multiple processing cores, or multiple processors.

In one example, processing device or logic circuit (1725) receives final results (1717, 1747) from inference engines (1709, 1739). Processing device or logic circuit (1725) is configured to determine whether final result (1717) matches final result (1747).

In response to determining that final result (1717) matches final result (1747), processing device or logic circuit (1725) outputs a final result based on final result (1717) and/or final result (1747), through host interface (1619) to host system (1621) for processing. In one example, processing device or logic circuit (1725) determines that final result (1717) matches final result (1747) by determining that final result (1717) is within a predetermined tolerance of final result (1747).

In one embodiment, vehicle (1761) includes control (e.g., control 1751). Control (1751) controls vehicle (1761) functions including, for example, steering (e.g., steering 1753), braking (e.g., braking 1755) and acceleration (e.g., acceleration 1757). Host system (1621) generates input for control (1751) based on final result (1717) and/or final result (1747) received from processing device or logic circuit (1725). For example, a final result output from processing device or logic circuit (1725) may identify an object in the path of vehicle (1761). Host system (1621) may receive the output from processing device or logic circuit (1725) and generate input for control (1751) (e.g., steering 1753 or braking 1755) to prevent vehicle (1761) from colliding with the identified object.

In one example, a first portion of an ANN (e.g., ANN 1711) is stored in memory device (1707) and a second portion of the ANN (e.g., ANN 1727) is stored in host system (1621). Memory device (1707) uses stored image data as input to ANN (1711) to generate inference results. Host system (1621) uses the inference results from memory device (1707) as input to ANN (1727) to provide results for controlling vehicle (1761).

In one example, camera (1701) includes memory device (1707) stacked with image sensor (1703). Memory device (1707) stores image stream (1705) from image sensor (1703). Memory device (1707) includes inference engine (1709) and inference engine (1709) includes a neural network accelerator configured to perform matrix arithmetic computations on data stored in memory device (1707). In one example, the neural network accelerator is a memristor crossbar array (1615). In one example, ANN (1711) is a spiking neural network.

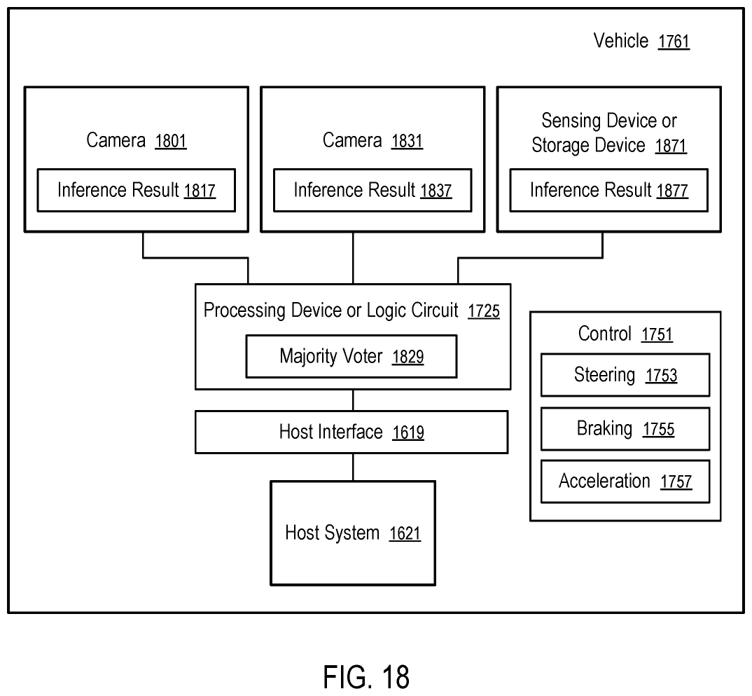

FIG. 18 shows vehicle (1761) configured to collect and process sensor data from redundant sensors according to one embodiment. Vehicle (1761) includes two cameras (e.g., cameras 1801, 1831) and a sensing device or storage device (e.g., sensing device or storage device 1871). In one example, cameras (1801, 1831) and sensing device or storage device (1871) are similar to sensing device (1601) of FIG. 16.

Cameras (1801, 1831) and sensing device or storage device (1871) each include inference engines and use data (e.g., image data 1605 or other input) as input to the inference engines. The cameras and the sensing or storage device each generate inference results (e.g., inference results 1817, 1837, 1877). Cameras (1801, 1831) and sensing device or storage device (1871) each communicate inference results to processing device or logic circuit (1725).

In one example, processing device or logic circuit (1725) includes a majority voter (e.g., majority voter 1829). Majority voter (1829) is configured to provide an output to host system (1621) based on inference results (1817, 1837, 1877) input to majority voter (1829). In one example, camera (1801) and camera (1831) may be video cameras, and sensing device or storage device (1871) may be a lidar sensor. Inference result (1817) from camera (1801) and inference result (1877) from lidar sensor (1871) may identify an object (e.g., a cyclist), and inference result (1837) from camera (1831) may not identify the object as a cyclist. Output from majority voter (1829) would identify the object as a cyclist since a majority of the inference results (1817, 1837, 1877) input to majority voter (1829) identified the object as a cyclist.

In one example, majority voter (1829) is implemented as a majority gate or other logic circuit having triple modular redundancy. The inputs to the majority voter may alternatively and/or additionally include various results from logic gates, logic circuits, and/or outputs from neural networks (e.g., 1611, 1741).

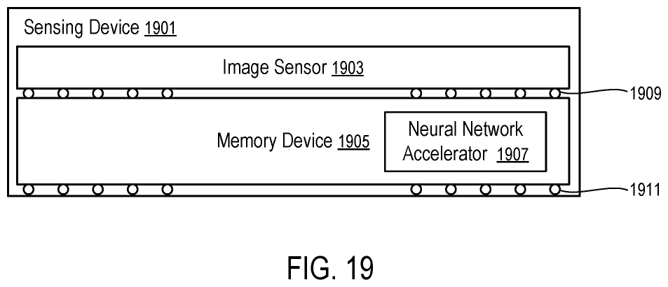

FIG. 19 shows sensing device (1901) stacked together with image sensor (1903) and memory device (1905) according to one embodiment. In one example, image sensor (1903) is similar to image sensor (1603) of FIG. 16, and memory device (1905) is similar to memory device (1607) of FIG. 16. Other devices (not shown) (e.g., processing devices, other memory devices, etc.) may be included in sensing device (1901). Memory device (1905) includes an inference engine and neural network accelerator (e.g., neural network accelerator 1907). In one embodiment, neural network accelerator (1907) is similar to neural network accelerator (1613) of FIG. 16.

The stacked image sensor (1903) and memory device (1905) are electrically connected and communicate (e.g., data and commands) through contacts (e.g., contacts 1909). Contacts (1909) may be, for example, Through-Silicon Vias (TSV), Ball-Grid-Array (BGA), wire leads, or other types of electrical contacts.

In one example, memory device (1905) includes contacts (1911). Contacts (1911) may communicate, for example, data and commands, with other components (not shown) within sensing device (1901) and/or with components or devices located external to sensing device (1901). Contacts (1909, 1911) may connect components within sensing device (1901) (e.g., image sensor 1903, memory device 1905, etc.) to a common substrate (e.g., flexible cable, flexible printed circuit, printed circuit board, semiconductor wafer or substrate, etc.).

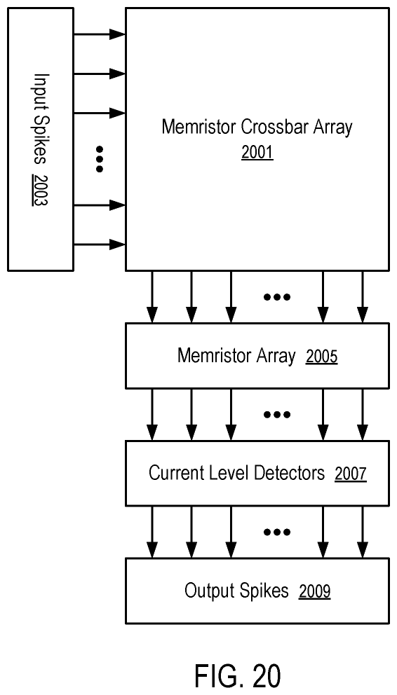

FIG. 20 shows a spiking neural network (e.g. a tile or portion of a spiking neural network that is formed using several tiles or portions) implemented using memristors according to one embodiment. In FIG. 20, a memristor crossbar array (2001) receives input voltage spikes (2003) to generate electric currents going through the memristor array (2005) that can function as an array of switches. Each memristor in the array (2005) is programmed to have a threshold for spiking detection. When the electric current flowing through the memristor is lower than the threshold, the memristor has a substantially same electrical resistance; and the switch implemented via the memristor is considered to be in an off state. However, when the electric current flowing through the memristor reaches its threshold, the electrical resistance of the memristor drops (e.g., close to zero), causing the current flowing through the memristor to increase significantly and spike; and in such a situation, the switch implemented via the memristor is considered to be in an on state. Once the switch implemented via the memristor is in the on state, the current flowing through the memristor can increase to at least a predefined level that is independent of the threshold of the memristor and that is higher than the currents that can flow through the memristors in the array (2001) before reaching the thresholds of the memristors in the array (2001).

An array of current level detectors (2007) can be configured to detect whether currents flowing through the memristors in the array (2005) have reached the levels corresponding to the switch-on state of the memristors in the array (2005). The detection can be performed based on detecting whether at least the predefined level of current is flowing through the corresponding memristors in the array (2005). Thus, the current detection operations of the current level detectors (2007) are independent of the thresholds of the memristors in the array (2005). Based on whether or not at least the predefined level of current is present in a memristor in the array, a corresponding detector in the array of current level detectors (2007) generates a digital signal indicating whether a spike in electric current is detected for a memristor in the array (2005). The collection of the outputs from the current level detectors (2007) provides the output spikes (2009). In one example, the output spikes (2009) can be provided as input to ANN 1611, 1711, 1741, and/or 1727).

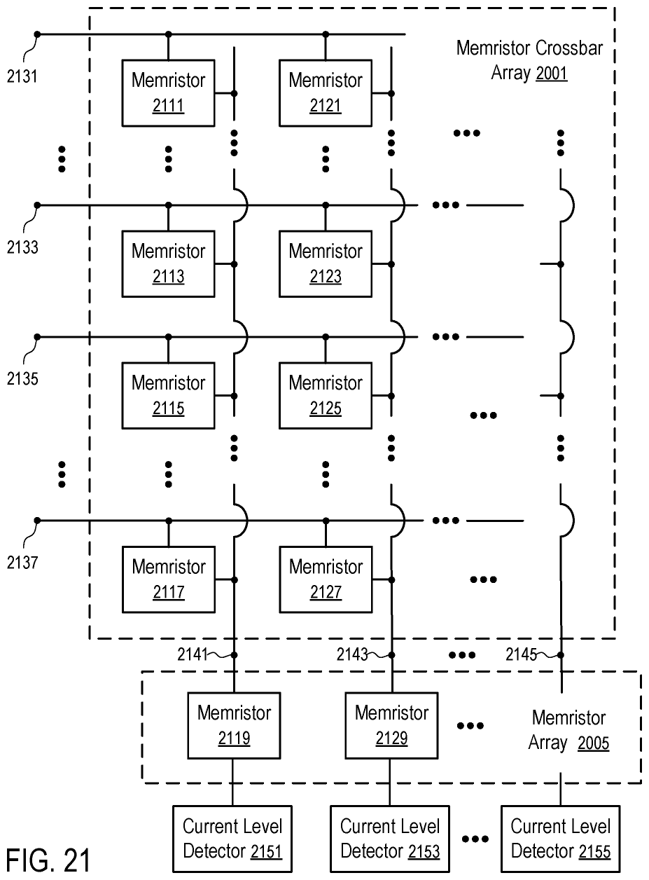

FIG. 21 illustrates the use of current spikes through a memristor array to detect spiking in a spiking neural network implemented using memristors according to one embodiment. In one example, the crossbar array (2001) and the memristor array (2005) of FIG. 20 can be implemented similarly as illustrated in FIG. 21.

In FIG. 21, each of the memristors in the crossbar array (2001) are connected between a wordline (e.g., 2131) and a bitline (e.g., 2141). The wordlines (2131, . . . , 2133, 2135, . . . , 2137) are configured to receive input voltages; the bitlines (2141, 2143, . . . , 2145) are configured to provide output currents; and the memristor array (2005) is configured to generate, according to activation level thresholds of spiking neurons, output current spikes corresponding to the spiking of neurons represented by the bitlines (2141, 2143, . . . , 2145).

For example, when a voltage is applied on the wordline (2131), the voltage generates currents flowing to the bitlines (2141, 2143, . . . , 2145) through the memristors (2111, 2121, . . . ) respectively. The contributions from the voltage applied on the wordline (2131) to the currents in the bitlines (2141, 2143, . . . , 2145) are proportional to weights and responses of neurons to the input represented by the voltage applied on the wordline (2131). The weights and responses of neurons can be implemented via programming the resistances of the memristors (2111, 2121, . . . ) respectively.

The bitlines (2141, 2143, . . . , 2145) sum the electric currents contributed from the voltages applied on the wordlines (2131, . . . , 2133, 2135, . . . , 2137) to the bitlines (2141, 2143, . . . , 2145). Thus, the currents in the bitlines (2141, 2143, . . . , 2145) correspond to the summation of the multiplications of the weights and responses of neurons, implemented via the programmed resistances of the crossbar array (2001), with the voltages of the wordlines (2131, . . . , 2133, 2135, . . . , 2137) that represent the input to the neurons.

For example, the contributions of the voltages on the wordlines (2131, . . . , 2133, 2135, . . . , 2137) to the bitline (2141) are summed via the currents flowing from the wordlines (2131, . . . , 2133, 2135, . . . , 2137) through the memristors (2111, . . . , 2113, 2115, . . . , 2117) to the bitline (2141); and the contributions of the voltages on the wordlines (2131, . . . , 2133, 2135, . . . , 2137) to the bitline (2143) are summed via the currents flowing from the wordlines (2131, . . . , 2133, 2135, . . . , 2137) through the memristors (2121, . . . , 2123, 2125, . . . , 2127) to the bitline (2143); etc.

Thus, the crossbar array (2001) performs Multiply-and-Accumulate (MAC) operations by converting the voltages on the wordlines (2131, . . . , 2133, 2135, . . . , 2137) to the currents on bitlines (2141, 2143, . . . , 2145).

In FIG. 21, instead of using ADCs to measure the currents flowing through the bitlines (2141, 2143, . . . , 2145), a memristor array (2005) is used to generate current spikes based on thresholds of memristors (2119, 2129, . . . ) that are connected to the bitlines (2141, 2143, . . . ) respectively.

For example, a memristor (2119) is connected to the bitline (2141) and programmed to have a threshold corresponding to the threshold of activation level of a spiking neuron. When the current on the bitline (2141) is less than the current threshold, the memristor (2119) has a first resistance corresponding to a switch-off state; and when the current on the bitline (2141) has reached the current threshold, the memristor (2119) has a second resistance corresponding to a switch-on state, which is significantly lower than the first resistance.

A current level detector (2151) is configured to detect whether or not the current on the bitline (2141) is at a level corresponding to the switch-on state of the memristor (2119), which indicates whether or not a spike is produced by a spiking neuron corresponding to the bitline (2141).

Thus, the outputs of the current level detectors (2151, 2153, . . . , 2155) correspond to the output spikes (2009) of the bitlines (2141, 2143, . . . , 2145).

For example, a spike train can be applied on the wordline (2131). The spike train is a time sequence of the voltages applied on the wordline (2131). Voltages in the spike train can be scheduled at a fixed time interval. The voltages in the spike train can be selected from two predetermined voltages. One of the voltages corresponds to the presence of a spike at a time instance in the spike train; and the other corresponds to the absence of a spike at a time instance in the spike train.

For example, a data item containing a number of bits can be converted into a spike train on the same number of time instances. The voltage applied at each of the time instances is based on the value of the corresponding bit in the data item.

When a set of spike trains are applied to the set of wordlines (2131, . . . , 2133, 2135, . . . , 2137) respectively, the outputs of the current level detectors (2151, 2153, . . . , 2155) generate a set of output spike trains, which can be further processed by, for example, another tile of spiking neural network.

The resistance values of the memristors in the crossbar array (2001) can be set to model the behavior of a spiking neural network. The resistance values of the memristors in the crossbar array (2001) can be changed via programming the memristors by selectively applying currents and/or voltages. For example, after a memristor (e.g., 2111) is selected for programming, a voltage applied on the memristor (e.g., 2111) can be raised to place the memristor (e.g., 2111) in a switch-on state; and then programming pulses can be applied on the memristor (e.g., 2111) to adjust the resistance of the memristor (e.g., 2111) to a desired value. After the programming, the memristor (e.g., 2111) remembers its programmed resistance during its switch-off state, until the memristor (e.g., 2111) is again selected for programming under the switch-on state. A separate circuit can be used to select memristor (e.g., 2111) and program the resistance of the memristor (e.g., 2111).

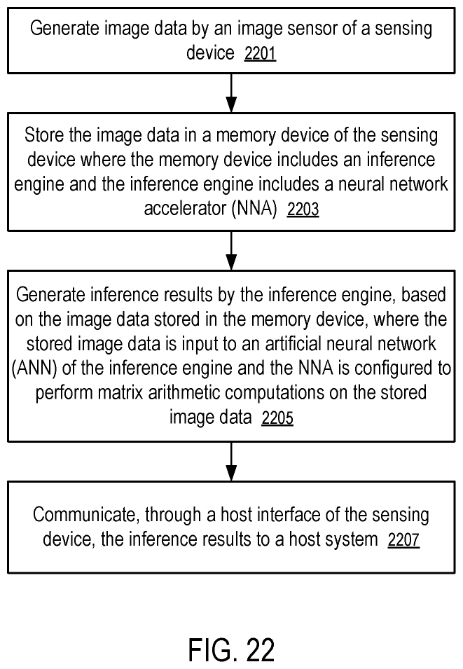

FIG. 22 shows a method implemented in a sensing device with a neural network accelerator according to one embodiment. Image data is generated by an image sensor of a sensing device. The image data is stored in a memory device that includes an inference engine and a neural network accelerator. Inference results are generated by the inference engine and communicated to a host system. For example, the method of FIG. 22 can be implemented in the system of FIG. 16. In one example, the host system is host system (1621). In one example, the sensing device is sensing device (1601).

The method of FIG. 22 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 22 is performed at least in part by one or more processing devices (e.g., a processing device (not shown) of memory device 1607 of FIG. 16).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2201, image data is generated by an image sensor of a sensing device. In one example, the image data is image data (1605). In one example, the image sensor is image sensor (1603).

At block 2203, the image data is stored in a memory device of the sensing device. The memory device includes an inference engine, and the inference engine includes a neural network accelerator. In one example, the memory device is memory device (1607). In one example, the inference engine is inference engine (1609).

At block 2205, inference results are generated by the inference engine, based on the image data stored in the memory device, where the stored image data is input to an artificial neural network of the inference engine and the neural network accelerator is configured to perform matrix arithmetic computations on the stored image data. In one example, the neural network accelerator is neural network accelerator (1613). In one example, the matrix arithmetic computations are performed by a memristor crossbar array (e.g., memristor crossbar array 1615).

At block 2207, the inference results are communicated to a host system through a host interface of the sensing device. In one example, the inference results are inference results (1617). In one example, the host interface is host interface (1619).

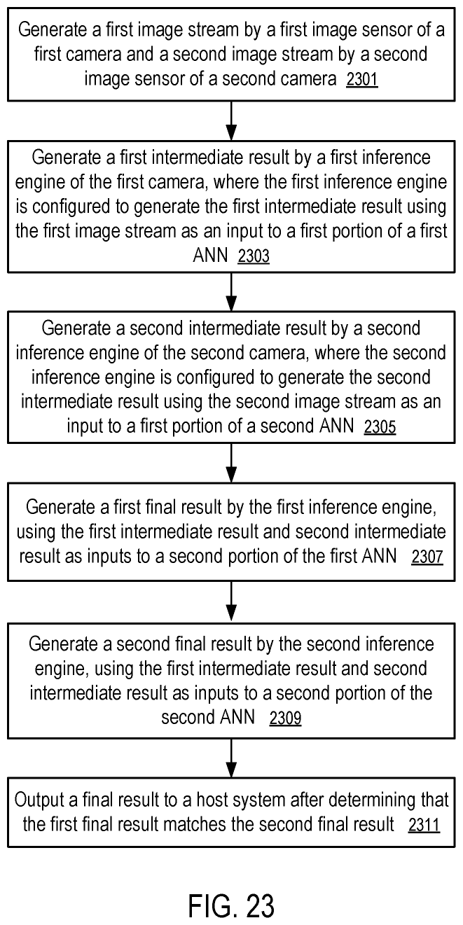

FIG. 23 shows a method implemented in a vehicle with redundant sensing devices according to one embodiment. A first image stream is generated by a first camera and a second image stream is generated by a second camera. A first intermediate result is generated by a first inference engine of the first camera and a second intermediate result is generated by a second inference engine of the second camera. A first final result is generated by the first inference engine based on the first intermediate result and the second intermediate result. A second final result is generated by the second inference engine based on the first intermediate result and the second intermediate result. A final result is output to a host system after determining that the first final result matches the second final result. For example, the method of FIG. 23 can be implemented in the system of FIG. 17. In one example, the first camera is camera (1701) and the second camera is camera (1731). In one example, the first image stream is image stream (1705), and the second image stream is image stream (1735).

The method of FIG. 23 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method of FIG. 23 is performed at least in part by one or more processing devices (e.g., processing devices (not shown) of memory device 1707 and memory device 1737 of FIG. 17).

Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

At block 2301, a first image stream is generated by a first image sensor of a first camera and a second image stream is generated by a second image sensor of a second camera. In one example, the first image sensor is image sensor (1703) and the second image sensor is image sensor (1733). In one example, camera (1701) and camera (1731) are video cameras.

At block 2303, a first intermediate result is generated by a first inference engine of the first camera, where the first inference engine is configured to generate the first intermediate result using the first image stream as an input to a first portion of a first ANN. In one example, the first ANN is ANN (1711). In one example, the first intermediate result is intermediate result (1713).

At block 2305, a second intermediate result is generated by a second inference engine of the second camera, where the second inference engine is configured to generate the second intermediate result using the second image stream as an input to a first portion of a second ANN. In one example, the second ANN is ANN (1741). In one example, the second intermediate result is intermediate result (1743).

At block 2307, a first final result is generated by the first inference engine using the first intermediate result and the second intermediate result as inputs to a second portion of the first ANN. In one example, the first final result is final result (1717).

At block 2309, a second final result is generated by the second inference engine using the first intermediate result and the second intermediate result as inputs to a second portion of the second ANN. In one example, the second final result is final result (1747).

At block 2311, a final result is output to a host system after determining that the first final result matches the second final result. In one example, the final result output is one of final result (1717) or final result (1747).

In one embodiment, a system includes: an image sensor (e.g., image sensor 1603) configured to generate image data (e.g., image data 1605); a memory device (e.g., memory device 1607) configured to store the generated image data; and a host interface (e.g., host interface 1619) configured to communicate with a host system (e.g., host system 1621). The memory device is stacked with the image sensor, and the memory device includes an inference engine (e.g., inference engine 1609) configured to generate inference results (e.g., inference results 1617) using the stored image data as input to an artificial neural network (ANN) (e.g., ANN 1611). The inference engine includes a neural network accelerator (e.g., neural network accelerator 1613) configured to perform matrix arithmetic computations on data stored in the memory device. The host interface is further configured to send the inference results to the host system for processing.

In one embodiment, the neural network accelerator includes a memristor crossbar array (e.g., memristor crossbar array 1615) configured to perform the matrix arithmetic computations.

In one embodiment, the matrix arithmetic computations include matrix multiplication and accumulation operations.

In one embodiment, the stored image data (e.g., a still image) is input to the memristor crossbar array.

In one embodiment, the memristor crossbar array includes memristors, and each memristor is connected between a wordline and a bitline.

In one embodiment, currents in bitlines of the memristor crossbar array correspond to summations of multiplications of weights and responses of neurons in the ANN; the neurons are implemented via programmed resistances of the memristors in the memristor crossbar array; and voltages of wordlines of the memristor crossbar array represent input to the neurons (e.g., representations of pixels in an image).

In one embodiment, the memristor crossbar array performs multiply-and-accumulate (MAC) operations by converting the voltages on the wordlines to currents on the bitlines.

In one embodiment, the ANN includes a spiking neural network (SNN).

In one embodiment, the memory device is a resistive random-access memory (RRAM).

In one embodiment, a system includes: a first camera (e.g., camera 1701) configured to generate a first image stream (e.g., image stream 1705), where the first camera includes a first inference engine (e.g., inference engine 1709) configured to generate a first intermediate result (e.g., intermediate result 1713) using the first image stream as input to a first portion of a first artificial neural network (ANN) (e.g., ANN 1711); a second camera (e.g., camera 1731) configured to generate a second image stream (e.g., image stream 1735), where the second camera includes a second inference engine (e.g., inference engine 1739) configured to generate a second intermediate result (e.g., intermediate result 1743) using the second image stream as input to a first portion of a second artificial neural network (ANN) (e.g., ANN 1741); a processing device or logic circuit (e.g., processing device or logic circuit 1725) configured to communicate with the first camera and the second camera; and a host interface to communicate inference results to a host system. The first camera further includes an interface (e.g., interface 1715) to communicate the first intermediate result to the second camera. The second camera further includes an interface (e.g., interface 1745) to communicate the second intermediate result to the first camera. The first inference engine uses the first intermediate result and the second intermediate result as input to a second portion of the first ANN to generate a first final result (e.g., final result 1717). The second inference engine uses the first intermediate result and the second intermediate result as input to a second portion of the second ANN to generate a second final result (e.g., final result 1747). The processing device or logic circuit is further configured to: determine whether the first final result matches the second final result; and in response to determining that the first final result matches the second final result, communicate, via the host interface, an output to the host system for processing. The output is based on at least one of the first final result or the second final result.

In one embodiment, determining whether the first final result matches the second final result includes determining whether the first final result is within a predetermined tolerance of the second final result.

In one embodiment, the system further includes: a sensing device or a storage device (e.g., sensing device or storage device 1871) configured to generate an inference result (e.g., inference result 1877), where the sensing device or storage device includes an interface to communicate the inference result to the processing device or logic circuit. The processing device or logic circuit includes a majority voter (e.g., majority voter 1829) configured to provide an output to the host system. An inference result (e.g., inference result 1817) from the first ANN, an inference result (e.g., inference result 1837) from the second ANN, and an inference result from the sensing device or storage device are input to the majority voter.

In one embodiment, the system further includes: a control (e.g., control 1751) for at least one of steering (e.g., steering 1753), braking (e.g., braking 1755), or acceleration (e.g., acceleration 1757) of a vehicle (e.g., vehicle 1761); where the host system generates input for the control based on at least one of the first final result or the second final result received from the processing device or logic circuit via the host interface.

In one embodiment, the first camera further includes: an image sensor (e.g., image sensor 1703) configured to generate the first image stream; and a memory device (e.g., memory device 1707) configured to store the first image stream. The memory device is stacked with the image sensor, and the memory device includes the first inference engine. The first inference engine includes a neural network accelerator configured to perform matrix arithmetic computations on data stored in the memory device.

In one embodiment, the neural network accelerator includes a memristor crossbar array configured to perform the matrix arithmetic computations. In one example, the memristor crossbar array is included in a neuromorphic memory device.

In one embodiment, the first ANN includes a spiking neural network (SNN).

In one embodiment, a method includes: generating, by an image sensor, image data; storing, by a memory device, the generated image data, where the memory device includes an inference engine configured to generate inference results using the stored image data as input to an artificial neural network (ANN), and where the inference engine includes a neural network accelerator configured to perform matrix arithmetic computations on the stored image data; and communicating by a host interface with a host system. The host interface is configured to send the inference results to the host system for processing.

In one embodiment, the neural network accelerator includes a memristor array configured to perform the matrix arithmetic computations, the matrix arithmetic computations include matrix multiplication and accumulation operations, and the method further includes providing the stored image data as input to the memristor array.

In one embodiment, the method further includes: receiving, by the host interface, sensor data (e.g., sensor data 1623) from the host system. The inference engine is further configured to generate the inference results using the sensor data as additional input to the ANN.

In one embodiment, the method further includes: storing a first portion of the ANN in the memory device. The host system stores a second portion of the ANN (e.g., ANN 1727). Generating the inference results includes using the stored image data as input to the first portion of the ANN. Processing by the host system includes using the inference results as input to the second portion of the ANN to provide a result for controlling a vehicle.

The present disclosure includes methods and apparatuses which perform the methods described above, including data processing systems which perform these methods, and computer readable media containing instructions which when executed on data processing systems cause the systems to perform these methods.

A typical data processing system may include includes an inter-connect (e.g., bus and system core logic), which interconnects a microprocessor(s) and memory. The microprocessor is typically coupled to cache memory.

The inter-connect interconnects the microprocessor(s) and the memory together and also interconnects them to input/output (I/O) device(s) via I/O controller(s). I/O devices may include a display device and/or peripheral devices, such as mice, keyboards, modems, network interfaces, printers, scanners, video cameras and other devices known in the art. In one embodiment, when the data processing system is a server system, some of the I/O devices, such as printers, scanners, mice, and/or keyboards, are optional.

The inter-connect can include one or more buses connected to one another through various bridges, controllers and/or adapters. In one embodiment the I/O controllers include a USB (Universal Serial Bus) adapter for controlling USB peripherals, and/or an IEEE-1394 bus adapter for controlling IEEE-1394 peripherals.

The memory may include one or more of: ROM (Read Only Memory), volatile RAM (Random Access Memory), and non-volatile memory, such as hard drive, flash memory, etc.

Volatile RAM is typically implemented as dynamic RAM (DRAM) which requires power continually in order to refresh or maintain the data in the memory. Non-volatile memory is typically a magnetic hard drive, a magnetic optical drive, an optical drive (e.g., a DVD RAM), or other type of memory system which maintains data even after power is removed from the system. The non-volatile memory may also be a random access memory.

The non-volatile memory can be a local device coupled directly to the rest of the components in the data processing system. A non-volatile memory that is remote from the system, such as a network storage device coupled to the data processing system through a network interface such as a modem or Ethernet interface, can also be used.

In the present disclosure, some functions and operations are described as being performed by or caused by software code to simplify description. However, such expressions are also used to specify that the functions result from execution of the code/instructions by a processor, such as a microprocessor.

Alternatively, or in combination, the functions and operations as described here can be implemented using special purpose circuitry, with or without software instructions, such as using Application-Specific Integrated Circuit (ASIC) or Field-Programmable Gate Array (FPGA). Embodiments can be implemented using hardwired circuitry without software instructions, or in combination with software instructions. Thus, the techniques are limited neither to any specific combination of hardware circuitry and software, nor to any particular source for the instructions executed by the data processing system.

While one embodiment can be implemented in fully functioning computers and computer systems, various embodiments are capable of being distributed as a computing product in a variety of forms and are capable of being applied regardless of the particular type of machine or computer-readable media used to actually effect the distribution.

At least some aspects disclosed can be embodied, at least in part, in software. That is, the techniques may be carried out in a computer system or other data processing system in response to its processor, such as a microprocessor, executing sequences of instructions contained in a memory, such as ROM, volatile RAM, non-volatile memory, cache or a remote storage device.

Routines executed to implement the embodiments may be implemented as part of an operating system or a specific application, component, program, object, module or sequence of instructions referred to as “computer programs.” The computer programs typically include one or more instructions set at various times in various memory and storage devices in a computer, and that, when read and executed by one or more processors in a computer, cause the computer to perform operations necessary to execute elements involving the various aspects.

A machine readable medium can be used to store software and data which when executed by a data processing system causes the system to perform various methods. The executable software and data may be stored in various places including for example ROM, volatile RAM, non-volatile memory and/or cache. Portions of this software and/or data may be stored in any one of these storage devices. Further, the data and instructions can be obtained from centralized servers or peer to peer networks. Different portions of the data and instructions can be obtained from different centralized servers and/or peer to peer networks at different times and in different communication sessions or in a same communication session. The data and instructions can be obtained in entirety prior to the execution of the applications. Alternatively, portions of the data and instructions can be obtained dynamically, just in time, when needed for execution. Thus, it is not required that the data and instructions be on a machine readable medium in entirety at a particular instance of time.

Examples of computer-readable media include but are not limited to non-transitory, recordable and non-recordable type media such as volatile and non-volatile memory devices, Read Only Memory (ROM), Random Access Memory (RAM), flash memory devices, floppy and other removable disks, magnetic disk storage media, optical storage media (e.g., Compact Disk Read-Only Memory (CD ROM), Digital Versatile Disks (DVDs), etc.), among others. The computer-readable media may store the instructions.

The instructions may also be embodied in digital and analog communication links for electrical, optical, acoustical or other forms of propagated signals, such as carrier waves, infrared signals, digital signals, etc. However, propagated signals, such as carrier waves, infrared signals, digital signals, etc. are not tangible machine readable medium and are not configured to store instructions.

In general, a machine readable medium includes any mechanism that provides (i.e., stores and/or transmits) information in a form accessible by a machine (e.g., a computer, network device, personal digital assistant, manufacturing tool, any device with a set of one or more processors, etc.).

In various embodiments, hardwired circuitry may be used in combination with software instructions to implement the techniques. Thus, the techniques are neither limited to any specific combination of hardware circuitry and software nor to any particular source for the instructions executed by the data processing system.

The above description and drawings are illustrative and are not to be construed as limiting. Numerous specific details are described to provide a thorough understanding. However, in certain instances, well known or conventional details are not described in order to avoid obscuring the description. References to one or an embodiment in the present disclosure are not necessarily references to the same embodiment; and, such references mean at least one.

In the foregoing specification, the disclosure has been described with reference to specific exemplary embodiments thereof. It will be evident that various modifications may be made thereto without departing from the broader spirit and scope as set forth in the following claims. The specification and drawings are, accordingly, to be regarded in an illustrative sense rather than a restrictive sense.

What is claimed is:

1. A system comprising:
an image sensor configured to generate image data;
a memory device configured to store the generated image data; and
a host interface configured to communicate with a host system;
wherein the memory device is stacked with the image sensor, and the memory device comprises an inference engine configured to generate inference results using the stored image data as input to an artificial neural network (ANN);
wherein the inference engine includes a neural network accelerator configured to perform matrix arithmetic computations on data stored in the memory device; and
wherein the host interface is further configured to send the inference results to the host system for processing.

2. The system of claim 1, wherein the memory device is a neuromorphic memory device, and the neural network accelerator includes a memristor crossbar array configured to perform the matrix arithmetic computations.

3. The system of claim 2, wherein the matrix arithmetic computations include matrix multiplication and accumulation operations.

4. The system of claim 2, wherein the stored image data is input to the memristor crossbar array.

5. The system of claim 1, wherein the memristor crossbar array comprises memristors, and each memristor is connected between a wordline and a bitline.

6. The system of claim 5, wherein:
currents in bitlines of the memristor crossbar array correspond to summation of multiplications of weights and responses of neurons in the ANN;
the neurons are implemented via programmed resistances of the memristors in the memristor crossbar array; and
voltages of wordlines of the memristor crossbar array represent input to the neurons.

7. The system of claim 6, wherein the memristor crossbar array performs multiply-and-accumulate (MAC) operations by converting the voltages on the wordlines to currents on the bitlines.

8. The system of claim 1, wherein the ANN comprises a spiking neural network (SNN).

9. The system of claim 1, wherein the memory device is a resistive random-access memory (RRAM).

10. A system comprising:
a first camera configured to generate a first image stream, wherein the first camera comprises a first inference engine configured to generate a first intermediate result using the first image stream as input to a first portion of a first artificial neural network (ANN);
a second camera configured to generate a second image stream, wherein the second camera comprises a second inference engine configured to generate a second intermediate result using the second image stream as input to a first portion of a second artificial neural network (ANN);
a processing device or logic circuit configured to communicate with the first camera and the second camera; and
a host interface to communicate inference results to a host system;
wherein the first camera further comprises an interface to communicate the first intermediate result to the second camera;
wherein the second camera further comprises an interface to communicate the second intermediate result to the first camera;
wherein the first inference engine uses the first intermediate result and the second intermediate result as input to a second portion of the first ANN to generate a first final result;
wherein the second inference engine uses the first intermediate result and the second intermediate result as input to a second portion of the second ANN to generate a second final result; and
wherein the processing device or logic circuit is further configured to:
determine whether the first final result matches the second final result; and
in response to determining that the first final result matches the second final result, communicate, via the host interface, an output to the host system for processing, wherein the output is based on at least one of the first final result or the second final result.

11. The system of claim 10, wherein the determining whether the first final result matches the second final result comprises determining whether the first final result is within a predetermined tolerance of the second final result.

12. The system of claim 10, further comprising:
a sensing device or a storage device configured to generate an inference result, wherein the sensing device or storage device comprises an interface to communicate the inference result to the processing device or logic circuit;
wherein the processing device or logic circuit comprises a majority voter configured to provide an output to the host system, and wherein an inference result from the first ANN, an inference result from the second ANN, and an inference result from the sensing device or storage device are input to the majority voter.

13. The system of claim 10, further comprising:
a control for at least one of steering, braking, or acceleration of a vehicle;
wherein the host system generates input for the control based on the at least one of the first final result or the second final result received from the processing device or logic circuit via the host interface.

14. The system of claim 10, wherein the first camera further comprises:
an image sensor configured to generate the first image stream; and
a memory device configured to store the first image stream;
wherein the memory device is stacked with the image sensor, and the memory device includes the first inference engine; and
wherein the first inference engine includes a neural network accelerator configured to perform matrix arithmetic computations on data stored in the memory device.

15. The system of claim 14, wherein the neural network accelerator includes a memristor crossbar array configured to perform the matrix arithmetic computations.

16. The system of claim 10, wherein the first ANN comprises a spiking neural network (SNN).

17. A method comprising:
generating, by an image sensor, image data;
storing, by a memory device, the generated image data, wherein the memory device comprises an inference engine configured to generate inference results using the stored image data as input to an artificial neural network (ANN), and wherein the inference engine includes a neural network accelerator configured to perform matrix arithmetic computations on the stored image data; and
communicating by a host interface with a host system, wherein the host interface is configured to send the inference results to the host system for processing.

18. The method of claim 17, wherein the memory device is a neuromorphic memory device, the neural network accelerator includes a memristor array configured to perform the matrix arithmetic computations, the matrix arithmetic computations include matrix multiplication and accumulation operations, and the method further comprises providing the stored image data as input to the memristor array.

19. The method of claim 17, further comprising:
receiving, by the host interface, sensor data from the host system;
wherein the inference engine is further configured to generate the inference results using the sensor data as additional input to the ANN.

20. The method of claim 17, further comprising:
storing a first portion of the ANN in the memory device;
wherein the host system stores a second portion of the ANN;
wherein generating the inference results comprises using the stored image data as input to the first portion of the ANN; and
wherein the processing by the host system comprises using the inference results as input to the second portion of the ANN to provide a result for controlling a vehicle.
